(19) United States
(12) Patent Application Publication
(10) Pub. No.: US 2026/0181948 A1
(43) Pub. Date: Jun. 25, 2026

(54) SEMICONDUCTOR DEVICE AND SEMICONDUCTOR MEMORY DEVICE

(71) Applicant: Kioxia Corporation, Tokyo (JP)

(72) Inventor: Takuya KIKUCHI, Yokkaichi (JP)

(73) Assignee: Kioxia Corporation, Tokyo (JP)

(21) Appl. No.: 19/249,217

(22) Filed: Jun. 25, 2025

(30) Foreign Application Priority Data
Dec. 19, 2024 (JP) 2024-224556

(51) Int. Cl. H10D 30/67; H10B 12/00; H10D 30/01

(52) U.S. Cl. CPC H10D 30/6728; H10B 12/33; H10D 30/6706; H10D 30/6735; H10D 30/6736; H10D 30/6757; H10D 30/0312; H10D 30/0318

(57) ABSTRACT

A semiconductor device of embodiments includes a first electrode, a second electrode, an oxide semiconductor layer between the first electrode and the second electrode, a gate electrode, a first insulating layer, a second insulating layer, and a gate insulating layer. Assuming that the thickness of the gate insulating layer between the first insulating layer and the oxide semiconductor layer is a first thickness, the thickness of the gate insulating layer between the second insulating layer and the oxide semiconductor layer is a second thickness, the thickness of the gate insulating layer between a first end of the gate electrode is a third thickness, and the thickness of the gate insulating layer between a second end of the gate electrode and the oxide semiconductor layer is a fourth thickness, the second thickness is larger than the first thickness or the fourth thickness is larger than the third thickness.

### CROSS-REFERENCE TO RELATED APPLICATION

This application is based upon and claims the benefit of priority from Japanese Patent Application No. 2024-224556, filed on Dec. 19, 2024, the entire contents of which are incorporated herein by reference.

### FIELD

Embodiments described herein relate generally to a semiconductor device and a semiconductor memory device.

### BACKGROUND

An oxide semiconductor transistor in which a channel is formed in an oxide semiconductor layer has an excellent characteristic that the channel leakage current during off operation is very small. For this reason, for example, the oxide semiconductor transistor can be applied as a switching transistor of a memory cell in a dynamic random access memory (DRAM).

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is a schematic cross-sectional view of the semiconductor device according to the first embodiment;

FIG. 4 is a schematic cross-sectional view of the semiconductor device according to the first embodiment;

FIG. 5 is a schematic cross-sectional view showing an example of a method for manufacturing the semiconductor device according to the first embodiment;

FIG. 6 is a schematic cross-sectional view showing an example of a method for manufacturing the semiconductor device according to the first embodiment;

FIG. 7 is a schematic cross-sectional view showing an example of a method for manufacturing the semiconductor device according to the first embodiment;

FIG. 8 is a schematic cross-sectional view showing an example of a method for manufacturing the semiconductor device according to the first embodiment;

FIG. 9 is a schematic cross-sectional view showing an example of a method for manufacturing the semiconductor device according to the first embodiment;

FIG. 10 is a schematic cross-sectional view showing an example of a method for manufacturing the semiconductor device according to the first embodiment;

FIG. 11 is a schematic cross-sectional view showing an example of a method for manufacturing the semiconductor device according to the first embodiment;

FIG. 12 is a schematic cross-sectional view showing an example of a method for manufacturing the semiconductor device according to the first embodiment;

FIG. 13 is a schematic cross-sectional view showing an example of a method for manufacturing the semiconductor device according to the first embodiment;

FIG. 14 is a schematic cross-sectional view showing an example of a method for manufacturing the semiconductor device according to the first embodiment;

FIG. 15 is a schematic cross-sectional view showing an example of a method for manufacturing the semiconductor device according to the first embodiment;

FIG. 16 is a schematic cross-sectional view showing an example of a method for manufacturing the semiconductor device according to the first embodiment;

FIG. 17 is a schematic cross-sectional view showing an example of a method for manufacturing the semiconductor device according to the first embodiment;

FIG. 18 is a schematic cross-sectional view showing an example of a method for manufacturing the semiconductor device according to the first embodiment;

FIG. 19 is a schematic cross-sectional view of a semiconductor device according to a comparative example;

FIG. 20 is a schematic cross-sectional view showing an example of a method for manufacturing the semiconductor device according to the comparative example;

FIG. 21 is a schematic cross-sectional view showing an example of a method for manufacturing the semiconductor device according to the comparative example;

FIG. 22 is a schematic cross-sectional view showing an example of a method for manufacturing the semiconductor device according to the comparative example;

FIG. 23 is a schematic cross-sectional view of a semiconductor device according to a first modification example of the first embodiment;

FIG. 24 is a schematic cross-sectional view of a semiconductor device according to a second modification example of the first embodiment;

FIG. 25 is a schematic cross-sectional view of a semiconductor device according to a third modification example of the first embodiment;

FIG. 26 is a schematic cross-sectional view of a semiconductor device according to a second embodiment;

FIG. 27 is a schematic cross-sectional view of a semiconductor device according to a third embodiment;

FIG. 28 is a schematic cross-sectional view of a semiconductor device according to a first modification example of the third embodiment;

FIG. 29 is a schematic cross-sectional view of a semiconductor device according to a second modification example of the third embodiment;

FIG. 30 is an equivalent circuit diagram of a semiconductor memory device according to a fourth embodiment; and

FIG. 31 is a schematic cross-sectional view of the semiconductor memory device according to the fourth embodiment.

### DETAILED DESCRIPTION

A semiconductor device of embodiments includes: a first electrode; a second electrode; an oxide semiconductor layer provided between the first electrode and the second electrode; a gate electrode facing the oxide semiconductor layer; a first insulating layer provided between the first electrode and the gate electrode; a second insulating layer provided between the gate electrode and the second electrode; and a gate insulating layer provided between the gate electrode and the oxide semiconductor layer, between the first insulating layer and the oxide semiconductor layer, and between the second insulating layer and the oxide semiconductor layer. In a first cross section parallel to a first direction connecting the first electrode and the second electrode, assuming that a thickness in a second direction perpendicular to the first direction of the gate insulating layer at a first position between the first insulating layer and the oxide semiconductor layer is a first thickness, a thickness in the second direction of the gate insulating layer at a second position between the second insulating layer and the oxide semiconductor layer is a second thickness, a thickness in the second direction of the gate insulating layer at a third position between a first end of the gate electrode on the first electrode side and the oxide semiconductor layer is a third thickness, and a thickness in the second direction of the gate insulating layer at a fourth position between a second end of the gate electrode on the second electrode side and the oxide semiconductor layer is a fourth thickness, the second thickness is larger than the first thickness or the fourth thickness is larger than the third thickness.

Hereinafter, embodiments will be described with reference to the diagrams. In addition, in the following description, the same or similar members and the like are denoted by the same reference numerals, and the description of the members and the like once described may be omitted as appropriate.

In addition, in this specification, the terms “on”, “below”, “upper”, and “lower” may be used for convenience. “On”, “below”, “upper”, and “lower” are terms that only indicate the relative positional relationship in the diagrams, but are not terms that define the positional relationship with respect to gravity.

The qualitative analysis and quantitative analysis of the chemical composition of members forming the semiconductor device and the semiconductor memory device in this specification can be performed by, for example, secondary ion mass spectrometry (SIMS), energy dispersive X-ray spectroscopy (EDX), and Rutherford back-scatting spectroscopy (RBS). In addition, when measuring the thickness of each member forming the semiconductor device and the semiconductor memory device, a distance between members, a crystal particle size, and the like, for example, a transmission electron microscope (TEM) can be used. In addition, for the identification of the constituent materials of members forming the semiconductor device and the semiconductor memory device and the measurement of the abundance ratio of the constituent materials, for example, X-ray photoelectron spectroscopy (XPS), hard X-ray photoelectron spectroscopy (HAXPES), and electron energy loss spectroscopy (EELS) can be used.

In this specification, “metal” is a general term for substances that exhibit metallic properties, and for example, metal compounds such as metal nitrides and metal carbides that exhibit metallic properties are also included in the scope of “metal”.

### First Embodiment

A semiconductor device according to a first embodiment includes: a first electrode; a second electrode; an oxide semiconductor layer provided between the first electrode and the second electrode; a gate electrode facing the oxide semiconductor layer; a first insulating layer provided between the first electrode and the gate electrode; a second insulating layer provided between the gate electrode and the second electrode; and a gate insulating layer provided between the gate electrode and the oxide semiconductor layer, between the first insulating layer and the oxide semiconductor layer, and between the second insulating layer and the oxide semiconductor layer. In a first cross section parallel to a first direction connecting the first electrode and the second electrode, assuming that a thickness in a second direction perpendicular to the first direction of the gate insulating layer at a first position between the first insulating layer and the oxide semiconductor layer is a first thickness, a thickness in the second direction of the gate insulating layer at a second position between the second insulating layer and the oxide semiconductor layer is a second thickness, a thickness in the second direction of the gate insulating layer at a third position between a first end of the gate electrode on the first electrode side and the oxide semiconductor layer is a third thickness, and a thickness in the second direction of the gate insulating layer at a fourth position between a second end of the gate electrode on the second electrode side and the oxide semiconductor layer is a fourth thickness, the second thickness is larger than the first thickness or the fourth thickness is larger than the third thickness.

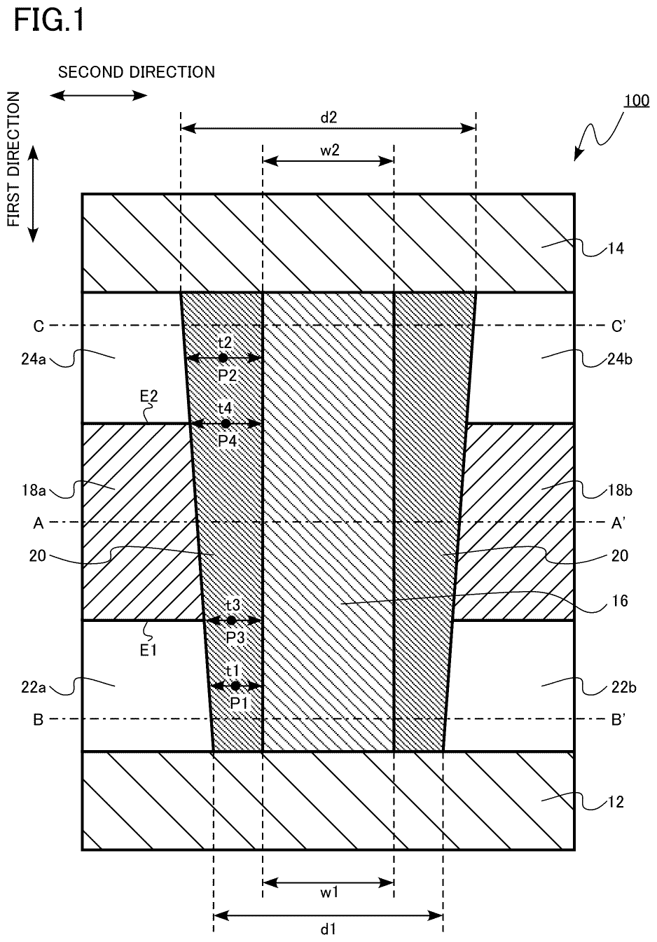

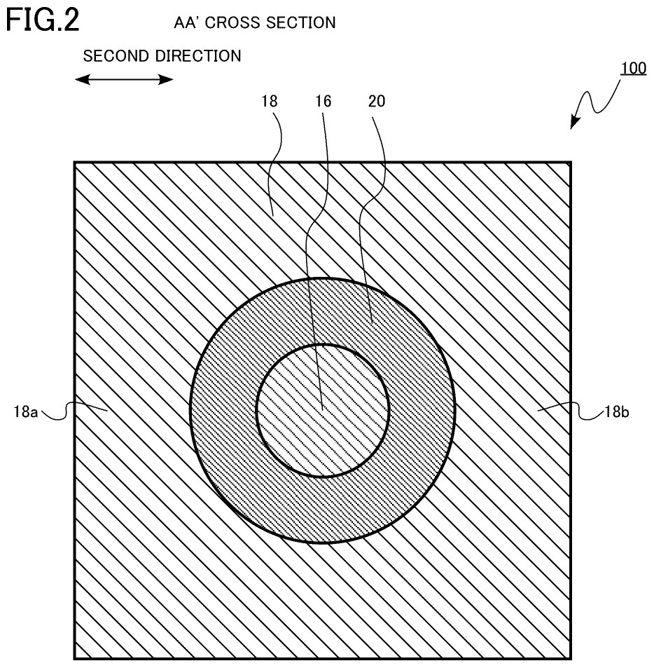

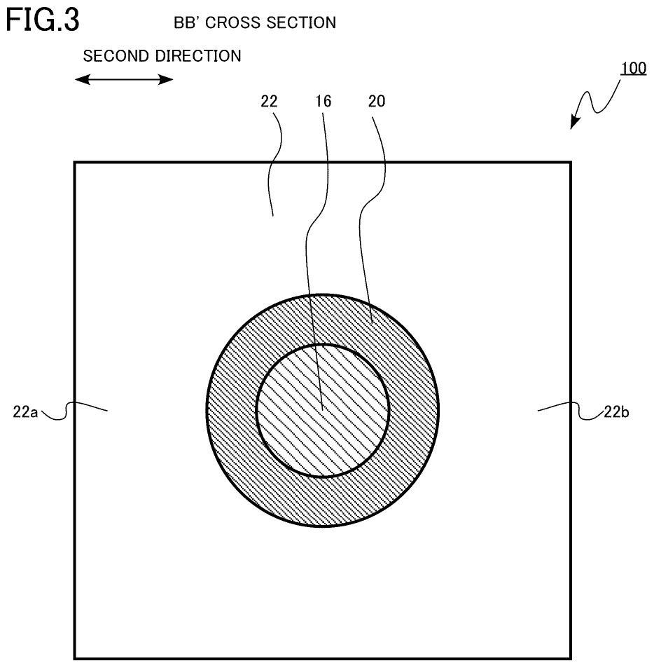

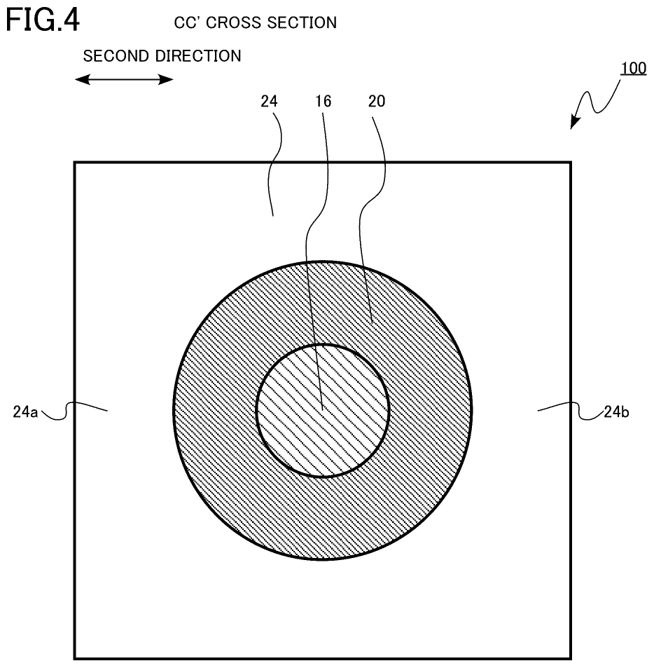

FIGS. 1 to 4 are schematic cross-sectional views of the semiconductor device according to the first embodiment. FIG. 2 is a cross-sectional view taken along the line AA′ of FIG. 1. FIG. 3 is a cross-sectional view taken along the line BB′ of FIG. 1. FIG. 4 is a cross-sectional view taken along the line CC′ of FIG. 1.

In FIG. 1, the vertical direction is referred to as a first direction. In FIG. 1, the horizontal direction is referred to as a second direction. The second direction is perpendicular to the first direction. The first direction is a direction connecting a lower electrode 12 and an upper electrode 14.

FIG. 1 shows a cross section parallel to the first direction. FIG. 1 is an example of the first cross section.

The semiconductor device according to the first embodiment is a transistor 100. The transistor 100 is an oxide semiconductor transistor in which a channel is formed in an oxide semiconductor. In the transistor 100, a gate electrode is provided so as to surround an oxide semiconductor layer in which a channel is formed. The transistor 100 is a so-called gate all around (GAA) transistor. The transistor 100 is a so-called vertical transistor.

The transistor 100 includes the lower electrode 12, the upper electrode 14, an oxide semiconductor layer 16, a gate electrode 18, a gate insulating layer 20, a first interlayer insulating layer 22, and a second interlayer insulating layer 24. The gate electrode 18 includes a first portion 18a and a second portion 18b. The first interlayer insulating layer 22 includes a third portion 22a and a fourth portion 22b. The second interlayer insulating layer 24 includes a fifth portion 24a and a sixth portion 24b.

The lower electrode 12 is an example of the first electrode. The upper electrode 14 is an example of the second electrode. The first interlayer insulating layer 22 is an example of the first insulating layer. The second interlayer insulating layer 24 is an example of the second insulating layer.

The lower electrode 12 is provided below the oxide semiconductor layer 16. The lower electrode 12 is electrically connected to the oxide semiconductor layer 16. The lower electrode 12 is in contact with, for example, the oxide semiconductor layer 16. The lower electrode 12 functions as a source electrode or a drain electrode of the transistor 100.

The lower electrode 12 is a conductor. The lower electrode 12 contains, for example, an oxide conductor. The lower electrode 12 is, for example, an oxide conductor layer.

The lower electrode 12 contains, for example, indium (In), tin (Sn), and oxygen (O). The lower electrode 12 contains, for example, indium tin oxide. The lower electrode 12 is, for example, an indium tin oxide layer.

The lower electrode 12 contains, for example, tin (Sn) and oxygen (O). The lower electrode 12 contains, for example, tin oxide. The lower electrode 12 is, for example, a tin oxide layer.

The lower electrode 12 contains, for example, a metal. The lower electrode 12 is, for example, a metal layer.

The lower electrode 12 contains, for example, tungsten (W), molybdenum (Mo), copper (Cu), aluminum (Al), titanium (Ti), zinc (Zn), or tantalum (Ta). The lower electrode 12 is, for example, a tungsten layer, a molybdenum layer, a copper layer, an aluminum layer, a titanium layer, a zinc layer, or a tantalum layer.

The lower electrode 12 may have, for example, a stacked structure of a plurality of conductors. The lower electrode 12 has, for example, a stacked structure of an oxide conductor layer and a metal layer. For example, the surface of the lower electrode 12 on the oxide semiconductor layer 16 side is an oxide conductor layer.

The upper electrode 14 is provided on the oxide semiconductor layer 16. The upper electrode 14 is electrically connected to the oxide semiconductor layer 16. The upper electrode 14 is in contact with, for example, the oxide semiconductor layer 16. The upper electrode 14 functions as a source electrode or a drain electrode of the transistor 100.

The upper electrode 14 is a conductor. The upper electrode 14 contains, for example, an oxide conductor. The upper electrode 14 is, for example, an oxide conductor layer.

The upper electrode 14 contains, for example, indium (In), tin (Sn), and oxygen (O). The upper electrode 14 contains, for example, indium tin oxide. The upper electrode 14 is, for example, an indium tin oxide layer.

The upper electrode 14 contains, for example, tin (Sn) and oxygen (O). The upper electrode 14 contains, for example, tin oxide. The upper electrode 14 is, for example, a tin oxide layer.

The upper electrode 14 contains, for example, a metal. The upper electrode 14 is, for example, a metal layer.

The upper electrode 14 contains, for example, tungsten (W), molybdenum (Mo), copper (Cu), aluminum (Al), titanium (Ti), or tantalum (Ta). The upper electrode 14 is, for example, a tungsten layer, a molybdenum layer, a copper layer, an aluminum layer, a titanium layer, or a tantalum layer.

The upper electrode 14 may have, for example, a stacked structure of a plurality of conductors. The upper electrode 14 has, for example, a stacked structure of an oxide conductor layer and a metal layer. For example, the surface of the upper electrode 14 on the oxide semiconductor layer 16 side is an oxide conductor layer.

The lower electrode 12 and the upper electrode 14 are formed of, for example, the same material. The lower electrode 12 and the upper electrode 14 are, for example, oxide conductors containing indium (In), tin (Sn), and oxygen (O). The lower electrode 12 and the upper electrode 14 contain, for example, indium tin oxide. The lower electrode 12 and the upper electrode 14 are, for example, indium tin oxide layers.

The oxide semiconductor layer 16 is provided between the lower electrode 12 and the upper electrode 14. The oxide semiconductor layer 16 is in contact with, for example, the lower electrode 12. The oxide semiconductor layer 16 is in contact with, for example, the upper electrode 14.

In the oxide semiconductor layer 16, a channel serving as a current path is formed when the transistor 100 is turned on.

The oxide semiconductor layer 16 is an oxide semiconductor. The oxide semiconductor layer 16 is amorphous, for example.

The oxide semiconductor layer 16 contains, for example, zinc (Zn), oxygen (O), and at least one element selected from a group consisting of indium (In), gallium (Ga), silicon (Si), aluminum (Al), and tin (Sn). The oxide semiconductor layer 16 contains, for example, indium (In), gallium (Ga), zinc (Zn) and oxygen (O). The oxide semiconductor layer 16 contains, for example, indium gallium zinc oxide. The oxide semiconductor layer 16 is, for example, an indium gallium zinc oxide layer.

The oxide semiconductor layer 16 contains, for example, oxygen (O) and at least one element selected from a group consisting of titanium (Ti), zinc (Zn), and tungsten (W). The oxide semiconductor layer 16 contains, for example, titanium oxide, zinc oxide, or tungsten oxide. The oxide semiconductor layer 16 is, for example, a titanium oxide layer, a zinc oxide layer, or a tungsten oxide layer.

The oxide semiconductor layer 16 has a chemical composition different from the chemical composition of the lower electrode 12 and the chemical composition of the upper electrode 14, for example.

The oxide semiconductor layer 16 includes oxygen vacancies. The oxygen vacancies in the oxide semiconductor layer 16 function as donors.

The length of the oxide semiconductor layer 16 in the first direction is, for example, equal to or more than 40 nm and equal to or less than 200 nm. The length of the oxide semiconductor layer 16 in the second direction is, for example, equal to or more than 10 nm and equal to or less than 100 nm.

A first width (w1 in FIG. 1) in the second direction of a portion of the oxide semiconductor layer 16 in contact with the lower electrode 12 is substantially equal to, for example, a second width (w2 in FIG. 1) in the second direction of a portion of the oxide semiconductor layer 16 in contact with the upper electrode 14.

The gate electrode 18 faces the oxide semiconductor layer 16. The gate electrode 18 is provided so that its position coordinates in the first direction are a value between the position coordinates of the lower electrode 12 and the position coordinates of the upper electrode 14 in the first direction.

As shown in FIG. 2, the gate electrode 18 is provided so as to surround the oxide semiconductor layer 16. The gate electrode 18 is provided around the oxide semiconductor layer 16.

The gate electrode 18 is a conductor. The gate electrode 18 is, for example, a metal, a metal compound, or a semiconductor. The gate electrode 18 contains, for example, tungsten (W).

The length of the gate electrode 18 in the first direction is, for example, equal to or more than 10 nm and equal to or less than 100 nm.

The gate electrode 18 includes the first portion 18a and the second portion 18b in a first cross section parallel to the first direction. In the second direction, the oxide semiconductor layer 16 is provided between the first portion 18a and the second portion 18b.

The gate electrode 18 has a first end E1 on the lower electrode 12 side and a second end E2 on the upper electrode 14 side.

The gate insulating layer 20 is provided between the gate electrode 18 and the oxide semiconductor layer 16. As shown in FIG. 2, the gate insulating layer 20 is provided so as to surround the oxide semiconductor layer 16. The gate insulating layer 20 is provided between the lower electrode 12 and the upper electrode 14.

The gate insulating layer 20 is provided between the first interlayer insulating layer 22 and the oxide semiconductor layer 16. The gate insulating layer 20 is provided between the second interlayer insulating layer 24 and the oxide semiconductor layer 16.

The gate insulating layer 20 is in contact with, for example, the lower electrode 12. The gate insulating layer 20 is in contact with, for example, the upper electrode 14. The gate insulating layer 20 is, for example, spaced from the lower electrode 12. The gate insulating layer 20 is, for example, spaced from the upper electrode 14.

The gate insulating layer 20 is, for example, an oxide, a nitride, or an oxynitride. The gate insulating layer 20 contains, for example, silicon oxide, aluminum oxide, titanium oxide, tantalum oxide, hafnium oxide, silicon nitride, aluminum nitride, or silicon oxynitride. The gate insulating layer 20 is, for example, a silicon oxide layer, an aluminum oxide layer, a titanium oxide layer, a tantalum oxide layer, a hafnium oxide layer, a silicon nitride layer, an aluminum nitride layer, or a silicon oxynitride layer.

The gate insulating layer 20 may have, for example, a stacked structure. The thickness of the gate insulating layer 20 is, for example, equal to or more than 2 nm and equal to or less than 10 nm.

In the first cross section, the thickness in the second direction of the gate insulating layer 20 at a first position (P1 in FIG. 1) between the first interlayer insulating layer 22 and the oxide semiconductor layer 16 is defined as a first thickness (t1 in FIG. 1), the thickness in the second direction of the gate insulating layer 20 at a second position (P2 in FIG. 1) between the second interlayer insulating layer 24 and the oxide semiconductor layer 16 is defined as a second thickness (t2 in FIG. 1), the thickness in the second direction of the gate insulating layer 20 at a third position (P3 in FIG. 1) between the first end (E1 in FIG. 1) of the gate electrode 18 on the lower electrode 12 side and the oxide semiconductor layer 16 is defined as a third thickness (t3 in FIG. 1), and the thickness in the second direction of the gate insulating layer 20 at a fourth position (P4 in FIG. 1) between the second end (E2 in FIG. 1) of the gate electrode 18 on the upper electrode 14 side and the oxide semiconductor layer 16 is defined as a fourth thickness (t4 in FIG. 1).

The second thickness t2 is larger than the first thickness t1, or the fourth thickness t4 is larger than the third thickness t3. FIG. 1 shows a case where the second thickness t2 is larger than the first thickness t1 and the fourth thickness t4 is larger than the third thickness t3.

The second thickness t2 is, for example, equal to or more than 1.1 times and equal to or less than 1.5 times the first thickness t1. In addition, the fourth thickness t4 is, for example, equal to or more than 1.1 times and equal to or less than 1.5 times the third thickness t3.

In the transistor 100, the thickness of the gate insulating layer 20 is larger in a portion close to the upper electrode 14 than in a portion close to the lower electrode 12. The thickness of the gate insulating layer 20 increases, for example, in a direction from the lower electrode 12 to the upper electrode 14.

The first interlayer insulating layer 22 is provided between the lower electrode 12 and the gate electrode 18. The first interlayer insulating layer 22 includes the third portion 22a and the fourth portion 22b on a first face. In the second direction, the oxide semiconductor layer 16 is provided between the third portion 22a and the fourth portion 22b. In the second direction, the gate insulating layer 20 is provided between the third portion 22a and the fourth portion 22b.

As shown in FIG. 3, the first interlayer insulating layer 22 surrounds the gate insulating layer 20 and the oxide semiconductor layer 16.

The first interlayer insulating layer 22 is in contact with the gate insulating layer 20. The third portion 22a is in contact with the gate insulating layer 20. The fourth portion 22b is in contact with the gate insulating layer 20. The first interlayer insulating layer 22 is in contact with the lower electrode 12.

The second interlayer insulating layer 24 is provided between the gate electrode 18 and the upper electrode 14. The second interlayer insulating layer 24 includes the fifth portion 24a and the sixth portion 24b on the first face. In the second direction, the oxide semiconductor layer 16 is provided between the fifth portion 24a and the sixth portion 24b. In the second direction, the gate insulating layer 20 is provided between the fifth portion 24a and the sixth portion 24b.

As shown in FIG. 4, the second interlayer insulating layer 24 surrounds the gate insulating layer 20 and the oxide semiconductor layer 16.

The second interlayer insulating layer 24 is in contact with the gate insulating layer 20. The fifth portion 24a is in contact with the gate insulating layer 20. The sixth portion 24b is in contact with the gate insulating layer 20. The second interlayer insulating layer 24 is in contact with the upper electrode 14.

The first interlayer insulating layer 22 and the second interlayer insulating layer 24 are insulators. The first interlayer insulating layer 22 and the second interlayer insulating layer 24 are, for example, oxides, nitrides, or oxynitrides. The first interlayer insulating layer 22 and the second interlayer insulating layer 24 contain, for example, silicon (Si) and oxygen (O). The first interlayer insulating layer 22 and the second interlayer insulating layer 24 contain, for example, silicon oxide. The first interlayer insulating layer 22 and the second interlayer insulating layer 24 are, for example, silicon oxides. The first interlayer insulating layer 22 and the second interlayer insulating layer 24 contain, for example, silicon (Si) and nitrogen (N). The first interlayer insulating layer 22 and the second interlayer insulating layer 24 contain, for example, silicon nitride. The first interlayer insulating layer 22 and the second interlayer insulating layer 24 are, for example, silicon nitrides.

The first interlayer insulating layer 22 and the second interlayer insulating layer 24 may be formed of different materials.

A first distance (d1 in FIG. 1) in the second direction between a portion where the third portion 22a is in contact with the lower electrode 12 and a portion where the fourth portion 22b is in contact with the lower electrode 12 is smaller than a second distance (d2 in FIG. 1) in the second direction between a portion where the fifth portion 24a is in contact with the upper electrode 14 and a portion where the sixth portion 24b is in contact with the upper electrode 14. On the first face, the outer boundary of the gate insulating layer 20 extends from the lower electrode 12 toward the upper electrode 14. The outer boundary of the gate insulating layer 20 has a so-called forward tapered shape.

Next, an example of a method for manufacturing the semiconductor device according to the first embodiment will be described.

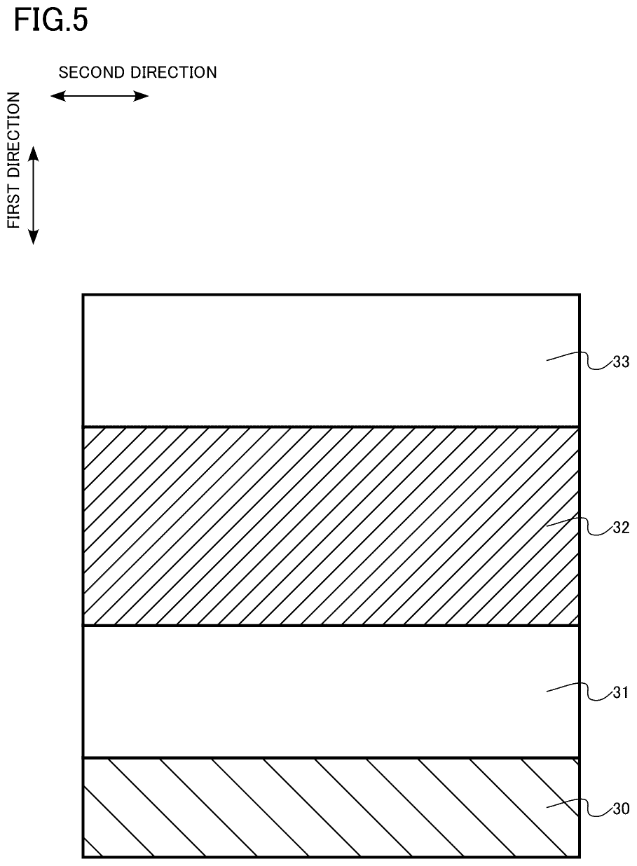

FIG. 5 to 18 are schematic cross-sectional views showing an example of the method for manufacturing the semiconductor device according to the first embodiment. FIGS. 5 to 18 each show a cross section corresponding to FIG. 1. FIGS. 5 to 18 are diagrams showing an example of a method for manufacturing the transistor 100.

Hereinafter, a case where the lower electrode 12 of the transistor 100 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, and the first interlayer insulating layer 22 and the second interlayer insulating layer 24 are silicon oxide layers will be described as an example.

First, a first silicon oxide film 31, a tungsten film 32, and a second silicon oxide film 33 are formed on a first indium tin oxide film 30 (FIG. 5). The first silicon oxide film 31, the tungsten film 32, and the second silicon oxide film 33 are formed by using, for example, a chemical vapor deposition method (CVD method).

The first indium tin oxide film 30 finally becomes the lower electrode 12. A part of the first silicon oxide film 31 finally becomes the first interlayer insulating layer 22. A part of the tungsten film 32 finally becomes the gate electrode 18. A part of the second silicon oxide film 33 finally becomes the second interlayer insulating layer 24.

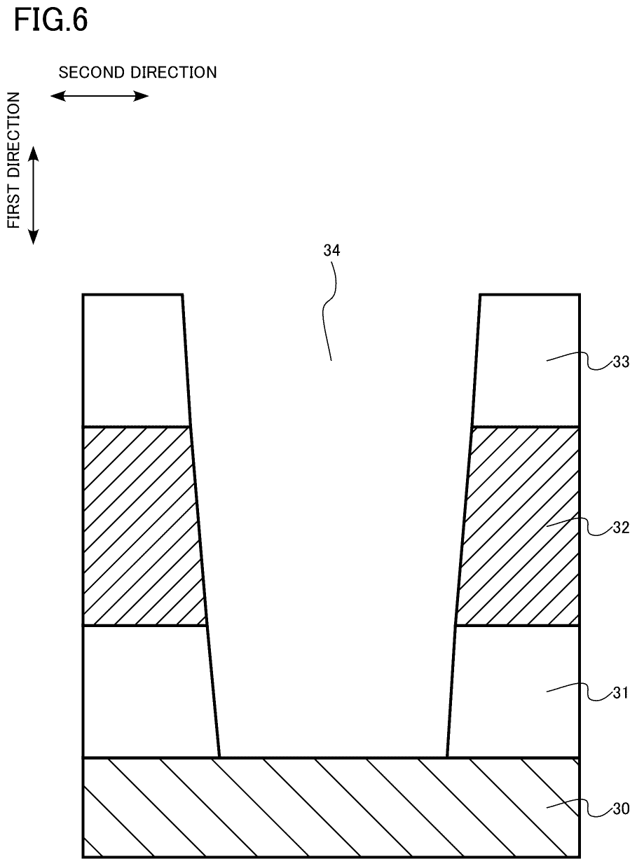

Then, an opening 34 that passes through the tungsten film 32 and the first silicon oxide film 31 and reaches the first indium tin oxide film 30 is formed from the surface of the second silicon oxide film 33 (FIG. 6). The opening 34 has, for example, a forward tapered shape in which the opening diameter decreases toward the first indium tin oxide film 30. The opening 34 is formed by using, for example, a lithography method and a reactive ion etching method (RIE method).

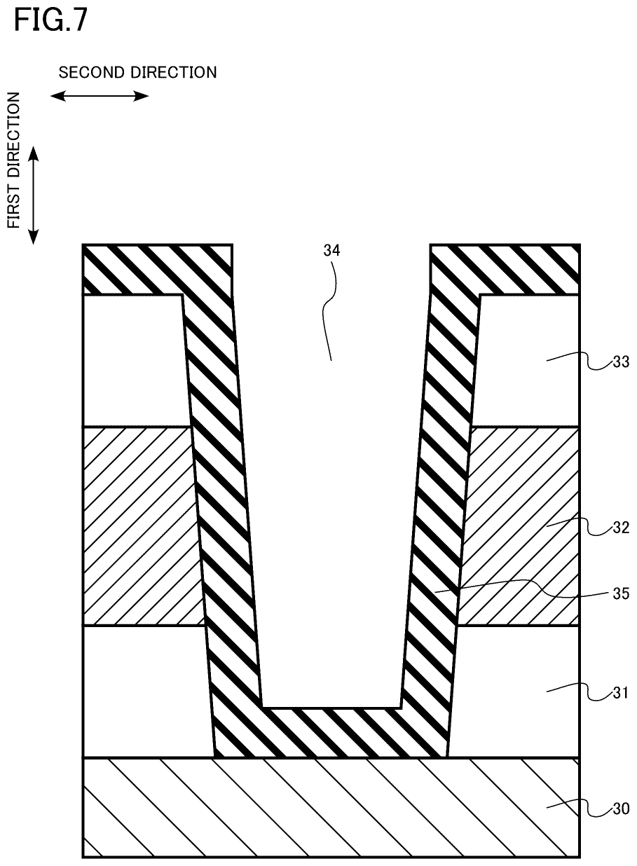

Then, a first silicon nitride film 35 is formed inside the opening 34 (FIG. 7). The first silicon nitride film 35 is formed by using, for example, an atomic layer deposition method (ALD method).

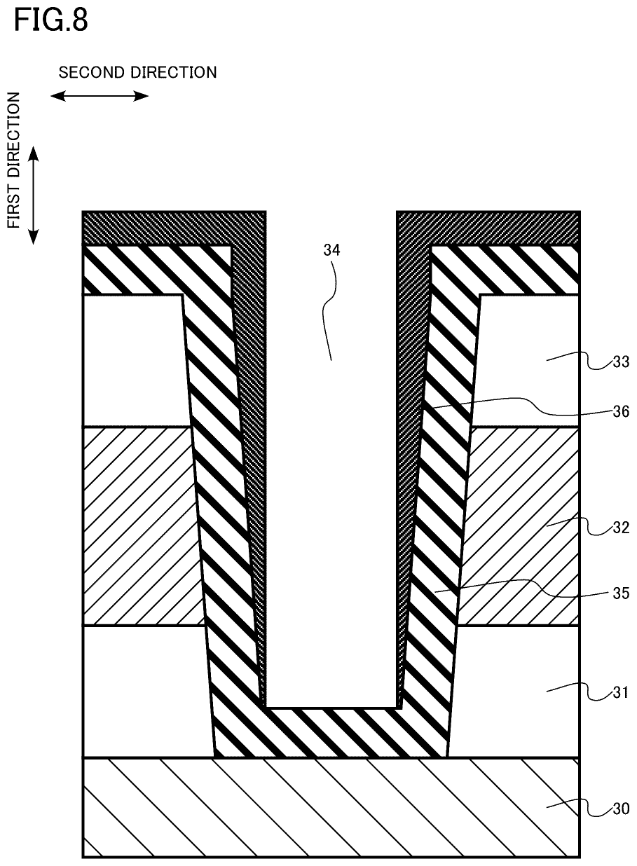

Then, a second silicon nitride film 36 is formed inside the opening 34 (FIG. 8). The second silicon nitride film 36 is formed by using, for example, a CVD method, which has a lower step coverage than the ALD method. The second silicon nitride film 36 is formed so that the film thickness above the opening 34 is larger than the film thickness below the opening 34.

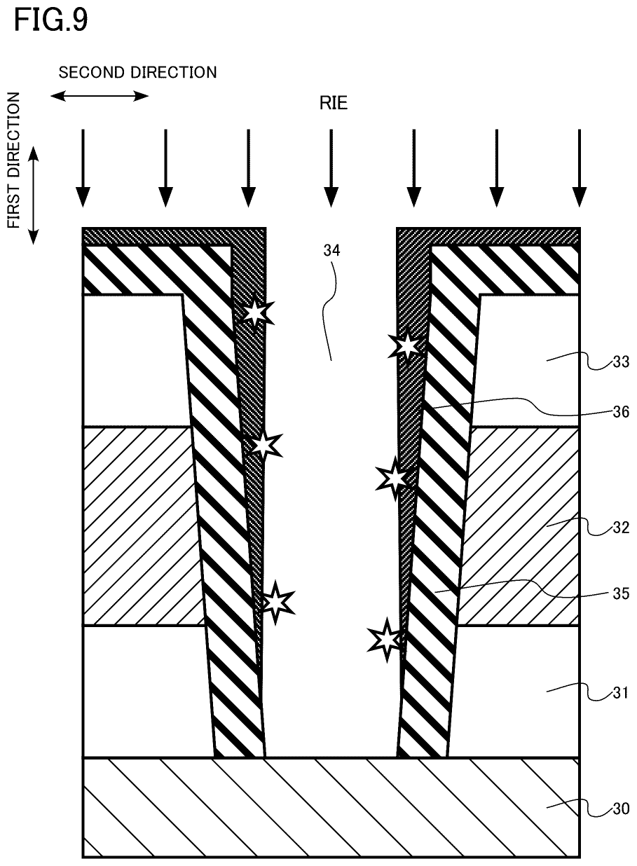

Then, the first silicon nitride film 35 at the bottom of the opening 34 is etched to expose the first indium tin oxide film 30 (FIG. 9). The first silicon nitride film 35 is etched by using the RIE method.

When the first silicon nitride film 35 is etched, the surfaces of the second silicon nitride film 36 and the first silicon nitride film 35 are exposed to RIE, and accordingly, processing damage is applied to the surfaces of the second silicon nitride film 36 and the first silicon nitride film 35.

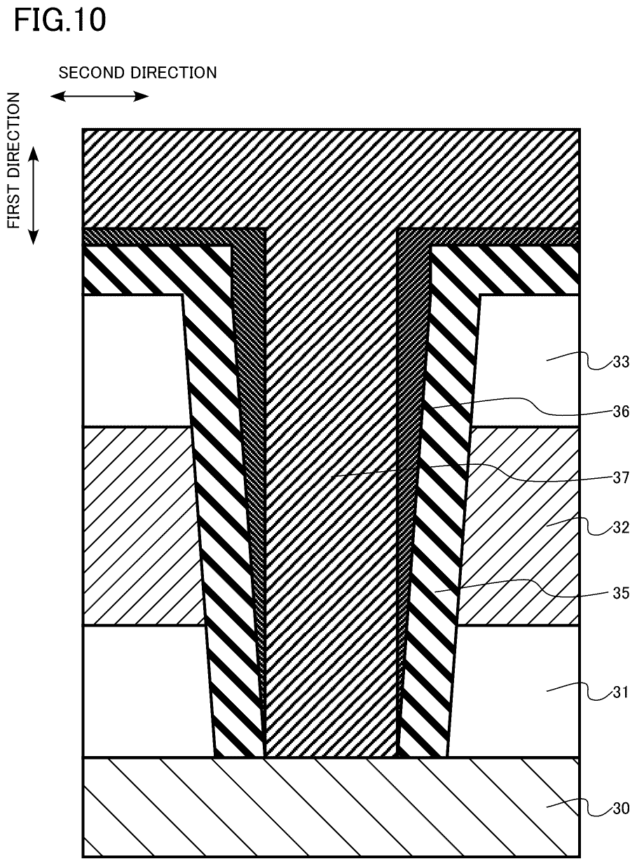

Then, the opening 34 is filled with a titanium nitride film 37 (FIG. 10). The titanium nitride film 37 is formed by using, for example, an ALD method. In addition, when the first silicon nitride film 35 and the second silicon nitride film 36 are removed by etching in a later process step, it is also possible to use an aluminum oxide film instead of the titanium nitride film 37 if the selectivity with respect to silicon nitride can be secured.

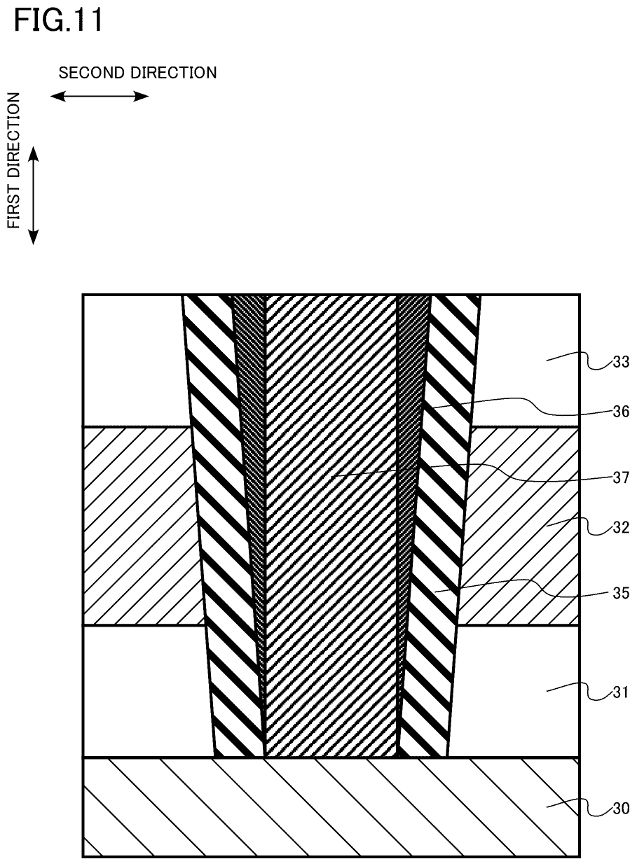

Then, an upper portion of the titanium nitride film 37 is removed, leaving the titanium nitride film 37 only in the opening 34 (FIG. 11). The upper portion of the titanium nitride film 37 is removed by using, for example, a chemical mechanical polishing method (CMP method).

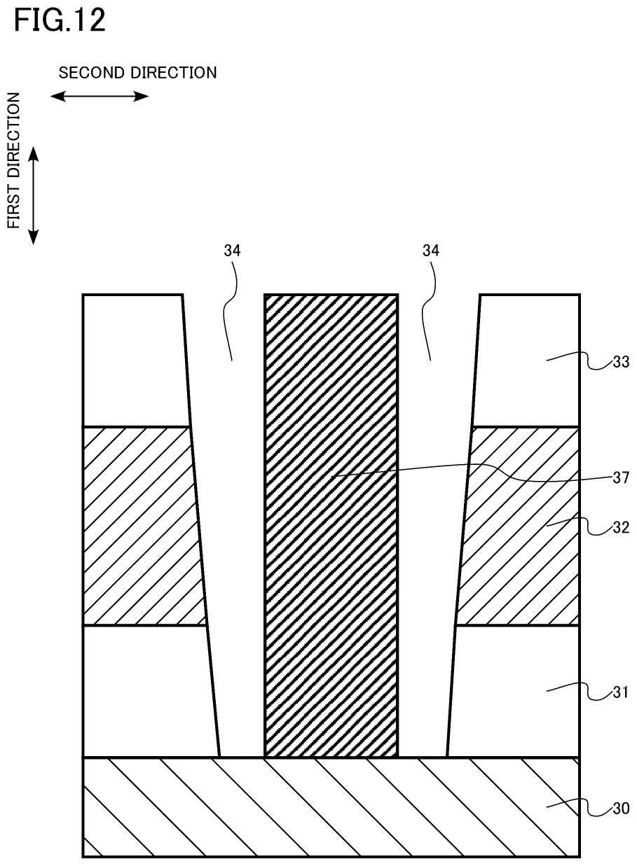

Then, the first silicon nitride film 35 and the second silicon nitride film 36 are removed by etching (FIG. 12). The titanium nitride film 37 remains in the opening 34 in a columnar shape. The first silicon nitride film 35 and the second silicon nitride film 36 are removed by using, for example, a wet etching method.

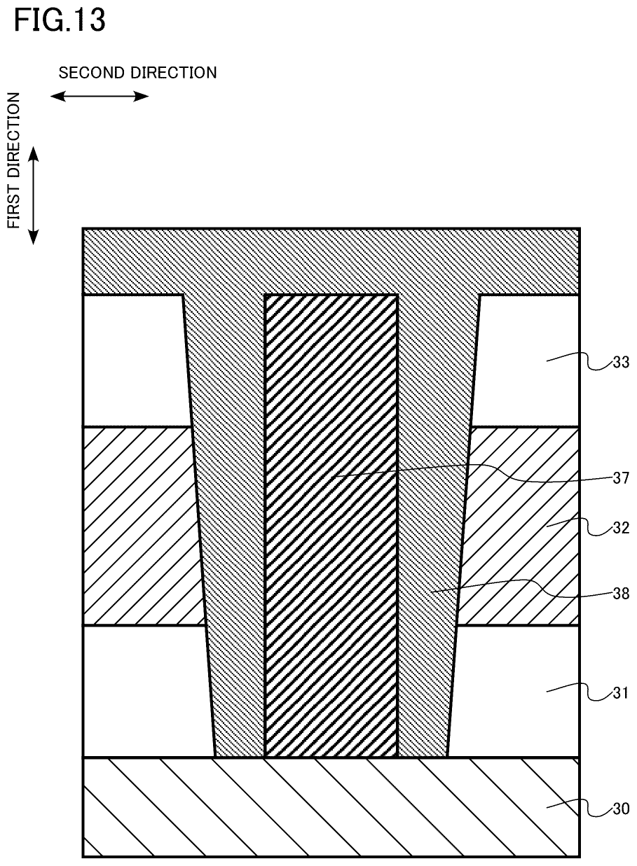

Then, the opening 34 is filled with a third silicon oxide film 38 (FIG. 13). The third silicon oxide film 38 is formed in a region where the second silicon nitride film 36 and the first silicon nitride film 35 have been removed. The third silicon oxide film 38 is formed by using, for example, an ALD method. Since the opening 34 has a shape wider at the top than at the bottom, the embeddability of the third silicon oxide film 38 is improved. A part of the third silicon oxide film 38 finally becomes the gate insulating layer 20.

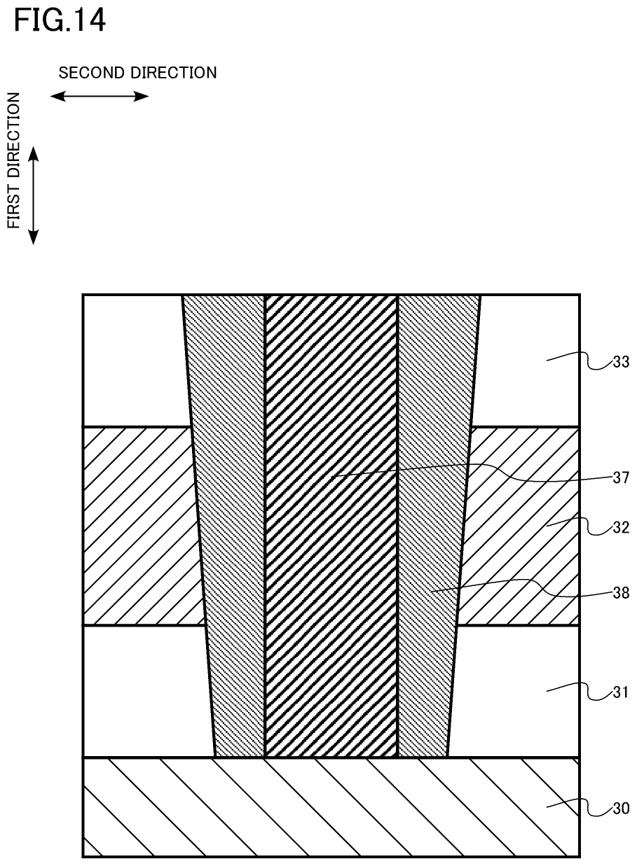

Then, an upper portion of the third silicon oxide film 38 is removed, leaving the third silicon oxide film 38 only in the opening 34 (FIG. 14). The upper portion of the third silicon oxide film 38 is removed by using, for example, a CMP method.

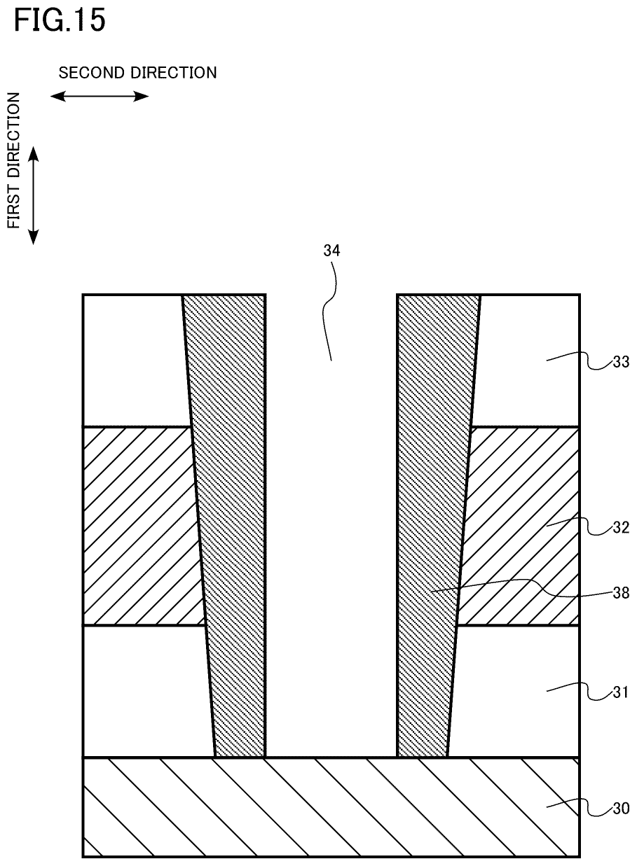

Then, the titanium nitride film 37 with a columnar shape in the opening 34 is removed (FIG. 15). The titanium nitride film 37 is removed by using, for example, a wet etching method.

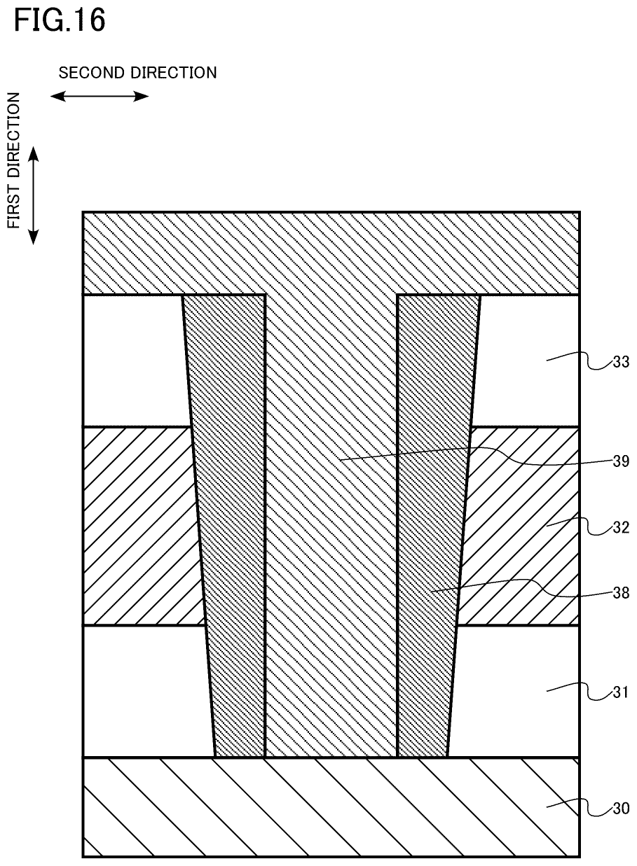

Then, the opening 34 is filled with an indium gallium zinc oxide film 39 (FIG. 16). The indium gallium zinc oxide film 39 is formed by using, for example, an ALD method. A part of the indium gallium zinc oxide film 39 finally becomes the oxide semiconductor layer 16.

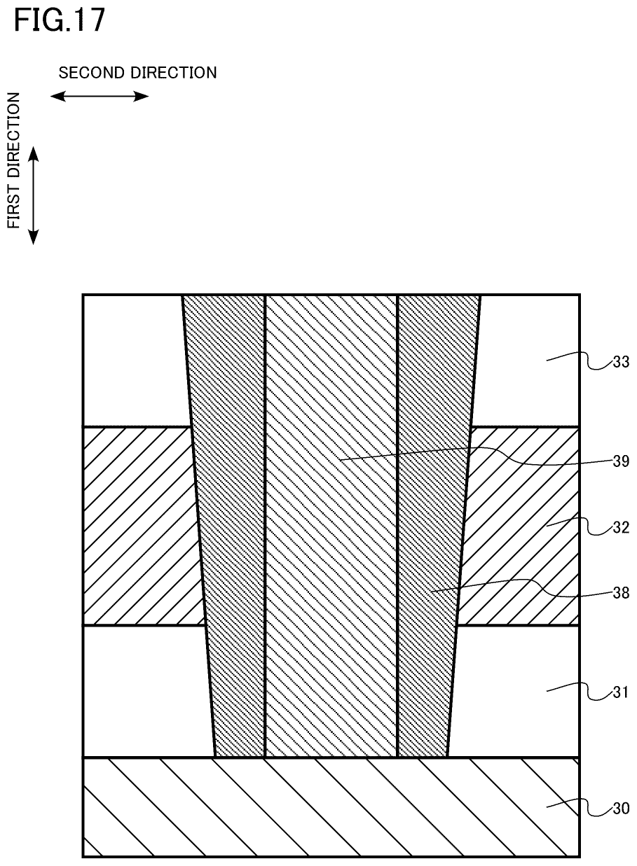

Then, an upper portion of the indium gallium zinc oxide film 39 is removed, leaving the indium gallium zinc oxide film 39 only in the opening 34 (FIG. 17). The upper portion of the indium gallium zinc oxide film 39 is removed by using, for example, a CMP method.

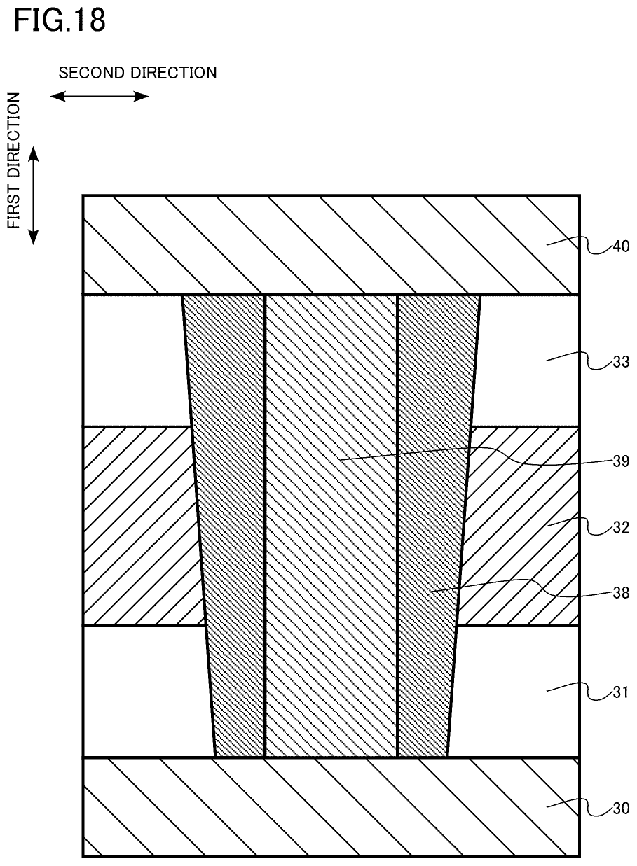

Then, a second indium tin oxide film 40 is formed on the indium gallium zinc oxide film 39 (FIG. 18). The second indium tin oxide film 40 is formed by using, for example, a sputtering method. The second indium tin oxide film 40 finally becomes the upper electrode 14.

By the manufacturing method described above, the transistor 100 shown in FIGS. 1 to 4 is manufactured.

Next, the function and effect of the semiconductor device according to the first embodiment will be described.

An oxide semiconductor transistor in which a channel is formed in an oxide semiconductor layer has an excellent characteristic that the channel leakage current during off operation is very small. For this reason, for example, it has been considered to apply the oxide semiconductor transistor to a switching transistor of a memory cell of a DRAM. Since the channel leakage current during off operation is very small, the charge storage characteristic of the DRAM is improved by applying the oxide semiconductor transistor as a switching transistor.

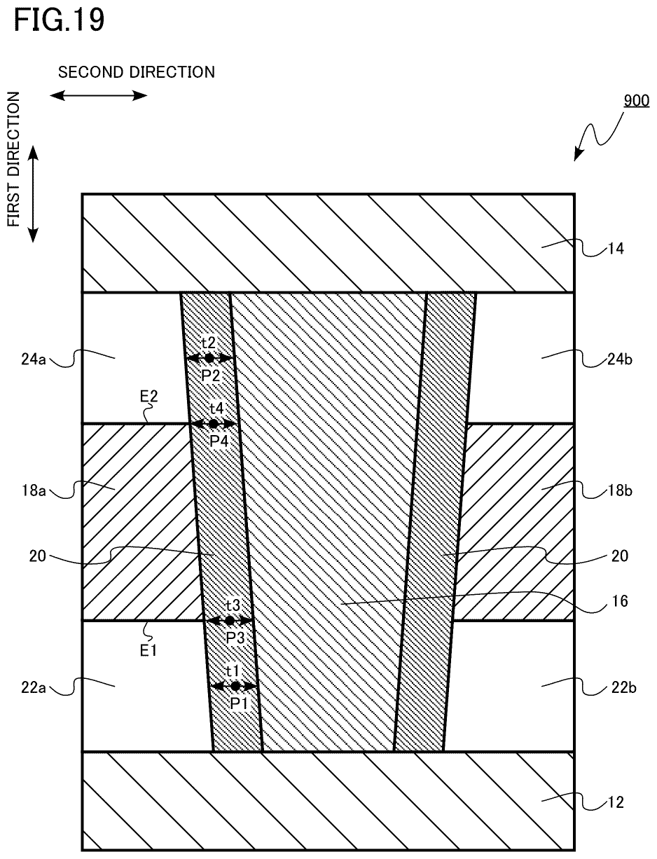

FIG. 19 is a schematic cross-sectional view of a semiconductor device according to a comparative example. FIG. 19 is a diagram corresponding to FIG. 1 of the semiconductor device according to the first embodiment.

The semiconductor device according to the comparative example is a transistor 900. The transistor 900 is an oxide semiconductor transistor. The transistor 900 is different from the transistor 100 according to the first embodiment in that the first thickness t1, the second thickness t2, the third thickness t3, and the fourth thickness t4 of the gate insulating layer 20 are equal. The transistor 900 is different from the transistor 100 in that the thickness of the gate insulating layer 20 in the second direction in the first cross section is constant between the lower electrode 12 and the upper electrode 14.

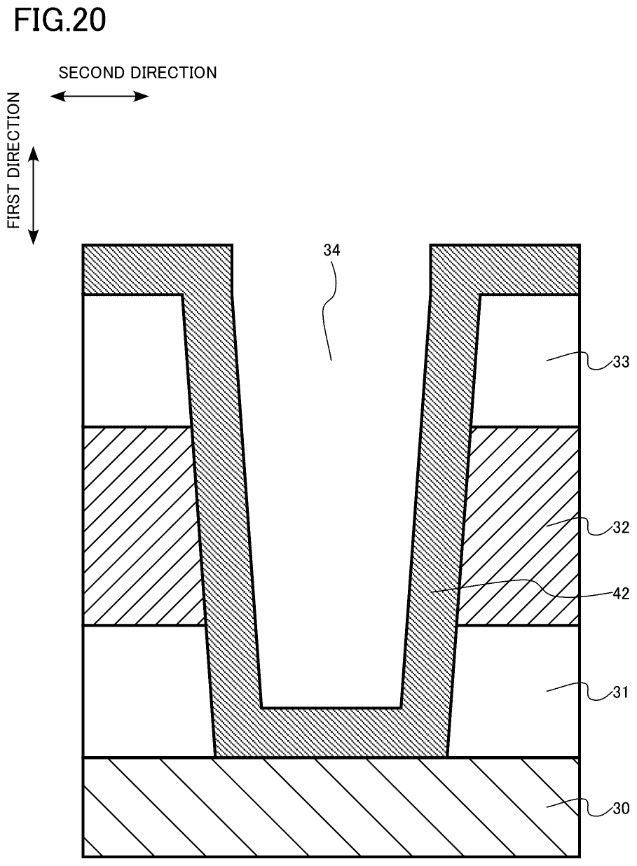

FIGS. 20 to 22 are schematic cross-sectional views showing an example of a method for manufacturing the semiconductor device according to the comparative example. FIGS. 20 to 22 each show a cross section corresponding to FIG. 19. FIGS. 20 to 22 are diagrams showing an example of a method for manufacturing the transistor 900.

The method for manufacturing the semiconductor device according to the comparative example is the same as the method for manufacturing the semiconductor device according to the first embodiment up to the formation of the opening 34, which passes through the tungsten film 32 and the first silicon oxide film 31 and reaches the first indium tin oxide film 30, from the surface of the second silicon oxide film 33.

Then, a silicon oxide film 42 is formed inside the opening 34 (FIG. 20). The silicon oxide film 42 is formed by using, for example, an ALD method. A part of the silicon oxide film 42 finally becomes the gate insulating layer 20.

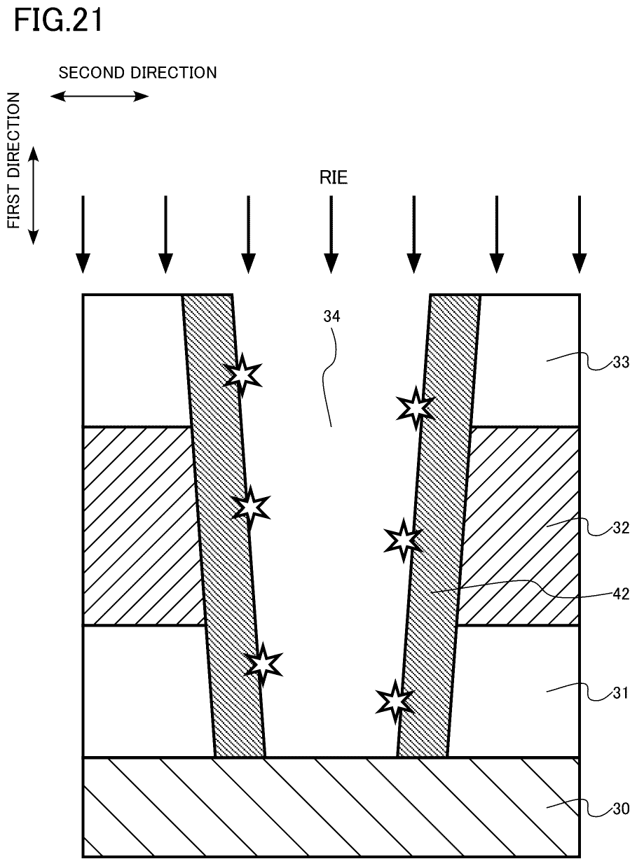

Then, the silicon oxide film 42 at the bottom of the opening 34 is etched to expose the first indium tin oxide film 30 (FIG. 21). The silicon oxide film 42 is etched by using an RIE method.

When the silicon oxide film 42 is etched, the surface of the silicon oxide film 42 is exposed to RIE, and accordingly, processing damage is applied to the surface of the silicon oxide film 42.

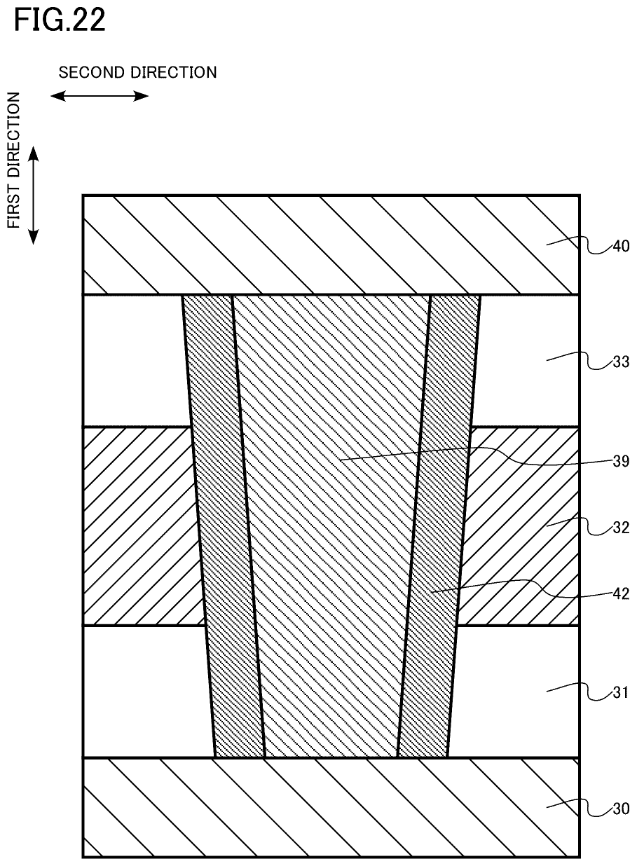

Thereafter, in the same manner as in the manufacturing method of the first embodiment, the opening 34 is filled with the indium gallium zinc oxide film 39, and the second indium tin oxide film 40 is further formed on the indium gallium zinc oxide film 39 (FIG. 22).

By the manufacturing method described above, the transistor 900 shown in FIG. 19 is manufactured.

In the method for manufacturing the transistor 900 according to the comparative example, when the silicon oxide film 42 at the bottom of the opening 34 is etched, the surface of the silicon oxide film 42 that becomes the gate insulating layer 20 is exposed to etching, and accordingly, processing damage is applied to the surface of the silicon oxide film 42. For this reason, for example, the reliability of the gate insulating layer 20 of the transistor 900 is reduced.

In the transistor 100 according to the first embodiment, the thickness of the gate insulating layer 20 is larger in a portion close to the upper electrode 14 than in a portion close to the lower electrode 12. By setting the thickness of the gate insulating layer 20 to be larger in a portion close to the upper electrode 14 than in a portion close to the lower electrode 12, it is possible to realize a method for manufacturing a transistor in which the reliability of the gate insulating layer 20 is improved.

In the method for manufacturing the transistor 100 according to the first embodiment, the first silicon nitride film 35 and the second silicon nitride film 36 are formed inside the opening 34 (FIG. 8). Then, the first silicon nitride film 35 at the bottom of the opening 34 is etched to expose the first indium tin oxide film 30 (FIG. 9). At this time, the surfaces of the second silicon nitride film 36 and the first silicon nitride film 35 are exposed to RIE, and accordingly, processing damage is applied to the surfaces of the second silicon nitride film 36 and the first silicon nitride film 35. However, since the second silicon nitride film 36 and the first silicon nitride film 35 are removed as shown in FIG. 12, the second silicon nitride film 36 and the first silicon nitride film 35 are not used as the gate insulating layer 20.

In the transistor 100 according to the first embodiment, the third silicon oxide film 38 is formed in a region where the second silicon nitride film 36 and the first silicon nitride film 35 have been removed (FIG. 13), and the third silicon oxide film 38 is used as the gate insulating layer 20. A portion of the third silicon oxide film 38 that is used as the gate insulating layer 20 is not exposed to RIE, and accordingly, no processing damage is applied to the portion of the third silicon oxide film 38. Therefore, compared with the transistor 900 according to the comparative example, the reliability of the gate insulating layer 20 of the transistor 100 is improved.

In the transistor 100 according to the first embodiment, a portion of the gate insulating layer 20 close to the upper electrode 14 is thicker than a portion of the gate insulating layer 20 close to the lower electrode 12. For this reason, in the method for manufacturing the transistor 100, the opening 34 when filled with the third silicon oxide film 38 has a shape wider at the top than at the bottom (FIG. 12). Therefore, the embeddability of the third silicon oxide film 38 is improved. Therefore, for example, it is possible to avoid a situation in which the third silicon oxide film 38 cannot be buried between the gate electrode 18 and the oxide semiconductor layer 16 and accordingly, the gate insulating layer 20 is not formed.

In addition, in the transistor 100 according to the first embodiment, a portion of the gate insulating layer 20 close to the upper electrode 14 is thicker than a portion of the gate insulating layer 20 close to the lower electrode 12. Therefore, for example, for the on-current flowing between the lower electrode 12 and the upper electrode 14, the asymmetry due to the current direction can be adjusted.

In the transistor 100, the fourth thickness t4 of the gate insulating layer 20 between the second end E2 of the gate electrode 18 and the oxide semiconductor layer 16 is larger than the third thickness t3 of the gate insulating layer 20 between the first end E1 of the gate electrode 18 and the oxide semiconductor layer 16. Therefore, for example, the channel resistance immediately below the second end E2 of the gate electrode 18 is higher than the channel resistance immediately below the first end E1 of the gate electrode 18.

In addition, the second thickness t2 of the gate insulating layer 20 between the second interlayer insulating layer 24 and the oxide semiconductor layer 16 is larger than the first thickness t1 of the gate insulating layer 20 between the first interlayer insulating layer 22 and the oxide semiconductor layer 16. Therefore, the strength of the fringe electric field applied from the gate electrode 18 in the oxide semiconductor layer 16 between the gate electrode 18 and the upper electrode 14 is weaker than that in the oxide semiconductor layer 16 between the gate electrode 18 and the lower electrode 12. Therefore, for example, the parasitic resistance of the oxide semiconductor layer 16 between the gate electrode 18 and the upper electrode 14 is larger than the parasitic resistance of the oxide semiconductor layer 16 between the gate electrode 18 and the lower electrode 12.

From this viewpoint, when the transistor 100 is in an on state, for example, electrons are less likely to flow from the upper electrode 14 to the lower electrode 12. In other words, in the transistor 100, when the transistor 100 in an on state, for example, the asymmetry of the on-current that the current is less likely to flow from the lower electrode 12 to the upper electrode 14 occurs.

For example, due to a difference between the contact resistance between the lower electrode 12 and the oxide semiconductor layer 16 and the contact resistance between the upper electrode 14 and the oxide semiconductor layer 16, electrons may flow easily from the lower electrode 12 to the upper electrode 14 when the transistor in an on state. In this case, the asymmetry of the on-current that the current is less likely to flow from the upper electrode 14 to the lower electrode 12 occurs.

In the transistor 100 according to the first embodiment, for example, due to the asymmetry of the on-current that can be realized by the difference in film thickness of the gate insulating layer 20, it is possible to offset the asymmetry of the on-current caused by the contact resistance between the lower electrode 12 and the upper electrode 14 and the oxide semiconductor layer 16. Therefore, according to the transistor 100 according to the first embodiment, it is possible to suppress the asymmetry of the on-current. In addition, when asymmetry is required in the magnitude of the on-current of the transistor 100, it is possible to realize the asymmetry of the on-current. Thus, according to the transistor 100, it is possible to adjust the asymmetry of the on-current.

As described above, according to the first embodiment, the reliability of the gate insulating layer 20 is improved to realize a semiconductor device with excellent transistor characteristics.

### First Modification Example

A semiconductor device according to a first modification example of the first embodiment is different from the semiconductor device according to the first embodiment in that a first width in a second direction of a portion of the oxide semiconductor layer in contact with the first electrode in the first cross section is smaller than a second width in the second direction of a portion of the oxide semiconductor layer in contact with the second electrode in the first cross section.

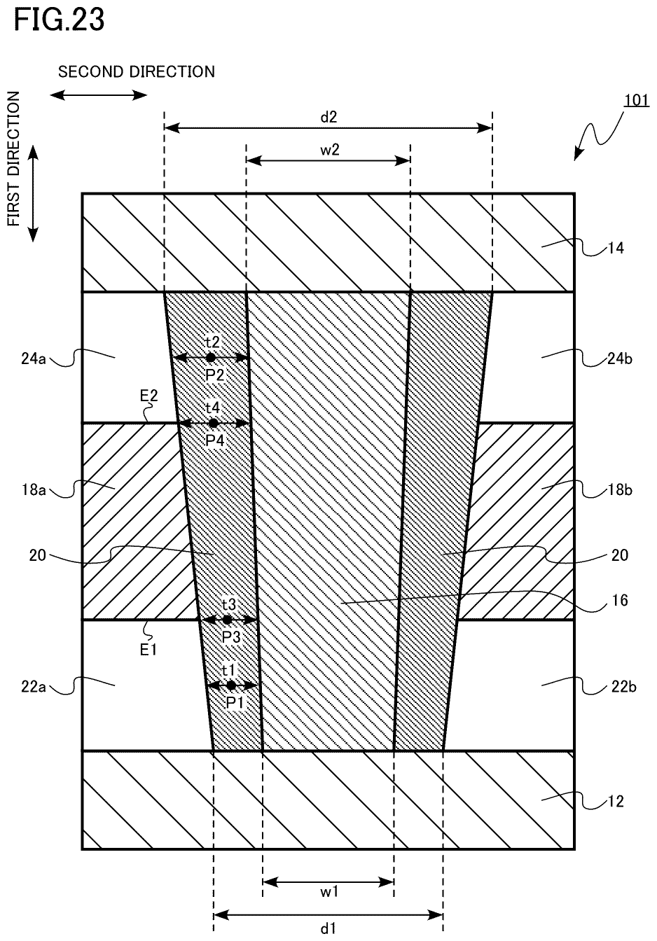

FIG. 23 is a schematic cross-sectional view of the semiconductor device according to the first modification example of the first embodiment. FIG. 23 is a diagram corresponding to FIG. 1 of the first embodiment.

The semiconductor device according to the first modification example of the first embodiment is a transistor 101. A first width (w1 in FIG. 23) in the second direction of a portion of the oxide semiconductor layer 16 in contact with the lower electrode 12 is smaller than a second width (w2 in FIG. 23) in the second direction of a portion of the oxide semiconductor layer 16 in contact with the upper electrode 14. The width of the oxide semiconductor layer 16 increases, for example, from the lower electrode 12 toward the upper electrode 14. The oxide semiconductor layer 16 has a so-called forward tapered shape.

According to the transistor 101 according to the first modification example of the first embodiment, the reliability of the gate insulating layer 20 is improved, similarly to the transistor 100 of the first embodiment. In addition, the contact area between the upper electrode 14 and the oxide semiconductor layer 16 can be made larger than the contact area between the lower electrode 12 and the oxide semiconductor layer 16. Therefore, for example, the contact resistance between the upper electrode 14 and the oxide semiconductor layer 16 can be reduced.

A fourth thickness t4 of the gate insulating layer 20 between the second end E2 of the gate electrode 18 and the oxide semiconductor layer 16 is larger than a third thickness t3 of the gate insulating layer 20 between the first end E1 of the gate electrode 18 and the oxide semiconductor layer 16. Therefore, for example, when the oxide semiconductor layer 16 does not have a tapered shape, the channel resistance immediately below the second end E2 of the gate electrode 18 is higher than the channel resistance immediately below the first end E1 of the gate electrode 18. In other words, the asymmetry of the channel resistance occurs. Therefore, for example, the asymmetry of the on-current may occur.

According to the transistor 101, since the oxide semiconductor layer 16 has a forward tapered shape, the area of the oxide semiconductor layer 16 facing the second end E2 of the gate electrode 18 can be made larger than the area of the oxide semiconductor layer 16 facing the first end E1 of the gate electrode 18 in a plane perpendicular to the first direction. Therefore, the asymmetry of the channel resistance is reduced to suppress the asymmetry of the on-current.

As described above, according to the first modification example of the first embodiment, as in the first embodiment, the reliability of the gate insulating layer 20 is improved to realize a semiconductor device with excellent transistor characteristics.

### Second Modification Example

A semiconductor device according to a second modification example of the first embodiment is different from the semiconductor device according to the first embodiment in that a first width in a second direction of a portion of the oxide semiconductor layer in contact with the first electrode in the first cross section is larger than a second width in the second direction of a portion of the oxide semiconductor layer in contact with the second electrode in the first cross section.

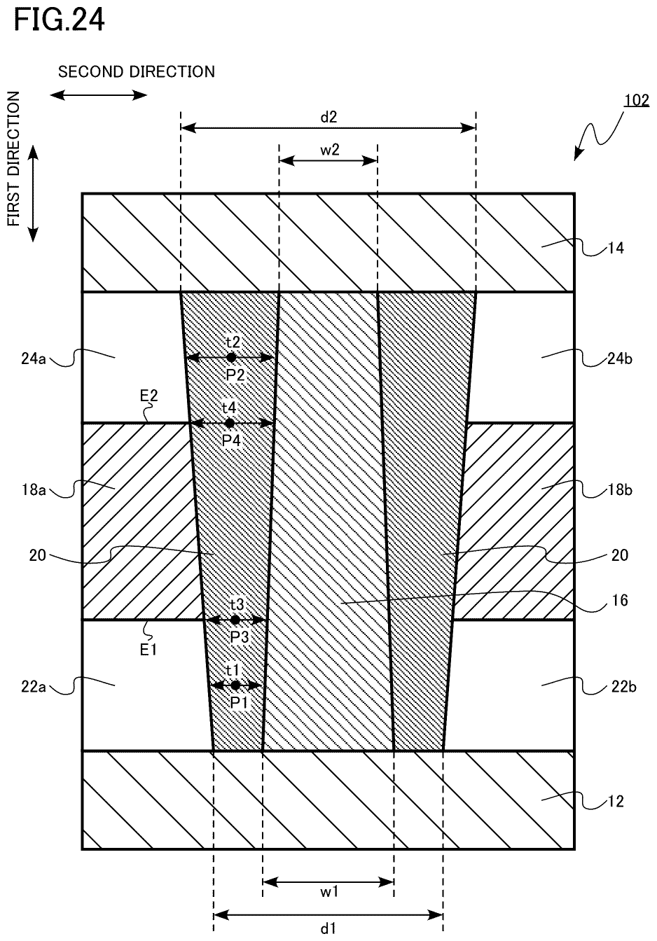

FIG. 24 is a schematic cross-sectional view of the semiconductor device according to the second modification example of the first embodiment. FIG. 24 is a diagram corresponding to FIG. 1 of the first embodiment.

The semiconductor device according to the second modification example of the first embodiment is a transistor 102. A first width (w1 in FIG. 24) in the second direction of a portion of the oxide semiconductor layer 16 in contact with the lower electrode 12 is larger than a second width (w2 in FIG. 24) in the second direction of a portion of the oxide semiconductor layer 16 in contact with the upper electrode 14. The width of the oxide semiconductor layer 16 decreases, for example, from the lower electrode 12 toward the upper electrode 14. The oxide semiconductor layer 16 has a so-called inverse tapered shape.

According to the transistor 102 according to the second modification example of the first embodiment, the reliability of the gate insulating layer 20 is improved, similarly to the transistor 100 according to the first embodiment. In addition, the contact area between the lower electrode 12 and the oxide semiconductor layer 16 can be made larger than the contact area between the upper electrode 14 and the oxide semiconductor layer 16. Therefore, for example, the contact resistance between the lower electrode 12 and the oxide semiconductor layer 16 can be reduced.

As described above, according to the second modification example of the first embodiment, as in the first embodiment, the reliability of the gate insulating layer 20 is improved to realize a semiconductor device with excellent transistor characteristics.

### Third Modification Example

A semiconductor device according to a third modification example of the first embodiment is different from the semiconductor device according to the first embodiment in that the gate insulating layer provided between the first insulating layer and the oxide semiconductor layer has a void.

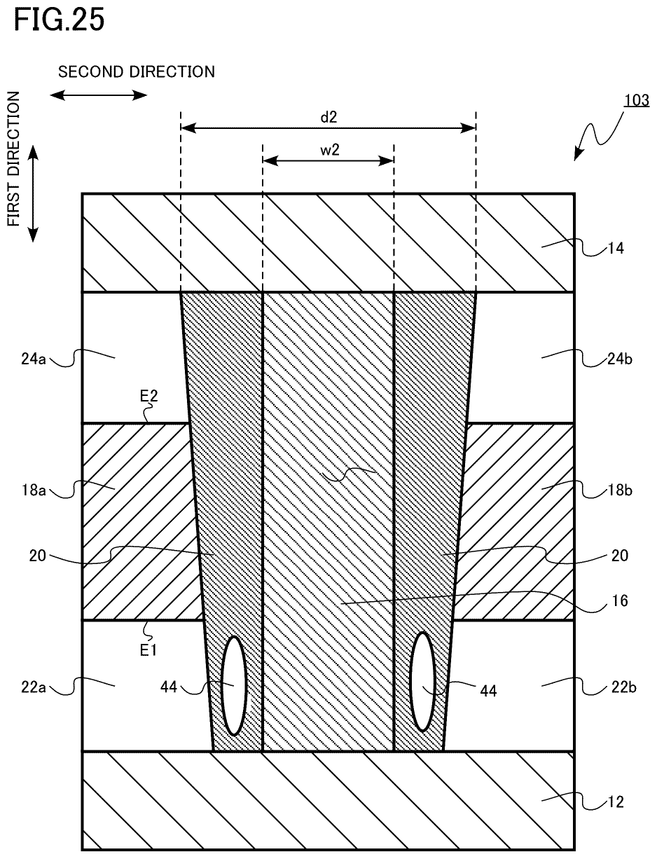

FIG. 25 is a schematic cross-sectional view of the semiconductor device according to the third modification example of the first embodiment. FIG. 25 is a diagram corresponding to FIG. 1 of the first embodiment.

The semiconductor device according to the third modification example of the first embodiment is a transistor 103. In the transistor 103, the gate insulating layer 20 between the first interlayer insulating layer 22 and the oxide semiconductor layer 16 has a void 44. The gate insulating layer 20 between the gate electrode 18 and the lower electrode 12 has a void 44. For example, in the method for manufacturing the semiconductor device according to the first embodiment, it is possible to form a void in the gate insulating layer 20 by adjusting the film forming conditions for the third silicon oxide film 38 that finally becomes the gate insulating layer 20.

No void 44 is present in the gate insulating layer 20 between the second interlayer insulating layer 24 and the oxide semiconductor layer 16 and in the gate insulating layer 20 between the gate electrode 18 and the oxide semiconductor layer 16.

The second thickness t2 of the gate insulating layer 20 between the second interlayer insulating layer 24 and the oxide semiconductor layer 16 is larger than the first thickness t1 of the gate insulating layer 20 between the first interlayer insulating layer 22 and the oxide semiconductor layer 16. Therefore, for example, when there is no void in the gate insulating layer 20 between the first interlayer insulating layer 22 and the oxide semiconductor layer 16, the strength of the fringe electric field applied from the gate electrode 18 in the oxide semiconductor layer 16 between the gate electrode 18 and the upper electrode 14 is weaker than that in the oxide semiconductor layer 16 between the gate electrode 18 and the lower electrode 12.

Therefore, for example, the parasitic resistance of the oxide semiconductor layer 16 between the gate electrode 18 and the upper electrode 14 is larger than the parasitic resistance of the oxide semiconductor layer 16 between the gate electrode 18 and the lower electrode 12. As a result, a vertical asymmetry occurs in the parasitic resistance of the transistor.

In the transistor 103 according to the third modification example of the first embodiment, the void 44 is provided in the gate insulating layer 20 between the first interlayer insulating layer 22 and the oxide semiconductor layer 16. The dielectric constant of the void is lower than the dielectric constant of, for example, an oxide or a nitride. Therefore, the strength of the fringe electric field applied to the oxide semiconductor layer 16 between the gate electrode 18 and the lower electrode 12 is weaker than that when there is no void 44 in the gate insulating layer 20. Therefore, for example, the difference between the parasitic resistance of the oxide semiconductor layer 16 between the gate electrode 18 and the upper electrode 14 and the parasitic resistance of the oxide semiconductor layer 16 between the gate electrode 18 and the lower electrode 12 is reduced. As a result, the vertical asymmetry of the parasitic resistance of the transistor is suppressed.

According to the transistor 103 according to the third modification example of the first embodiment, the reliability of the gate insulating layer 20 is improved, similarly to the transistor 100 according to the first embodiment. In addition, since the gate insulating layer 20 between the gate electrode 18 and the lower electrode 12 has the void 44, the vertical asymmetry of the parasitic resistance of the transistor 103 is suppressed.

As described above, according to the third modification example of the first embodiment, as in the first embodiment, the reliability of the gate insulating layer 20 is improved to realize a semiconductor device with excellent transistor characteristics.

As described above, according to the first embodiment and its modification examples, the reliability of the gate insulating layer 20 is improved to realize a semiconductor device with excellent transistor characteristics.

### Second Embodiment

A semiconductor device according to a second embodiment is different from the semiconductor device according to the first embodiment in that the gate insulating layer provided between the second insulating layer and the oxide semiconductor layer and the gate insulating layer provided between the gate electrode and the oxide semiconductor layer contain a material different from that of the gate insulating layer provided between the first insulating layer and the oxide semiconductor layer. Hereinafter, the description of a part of the content overlapping the first embodiment may be omitted.

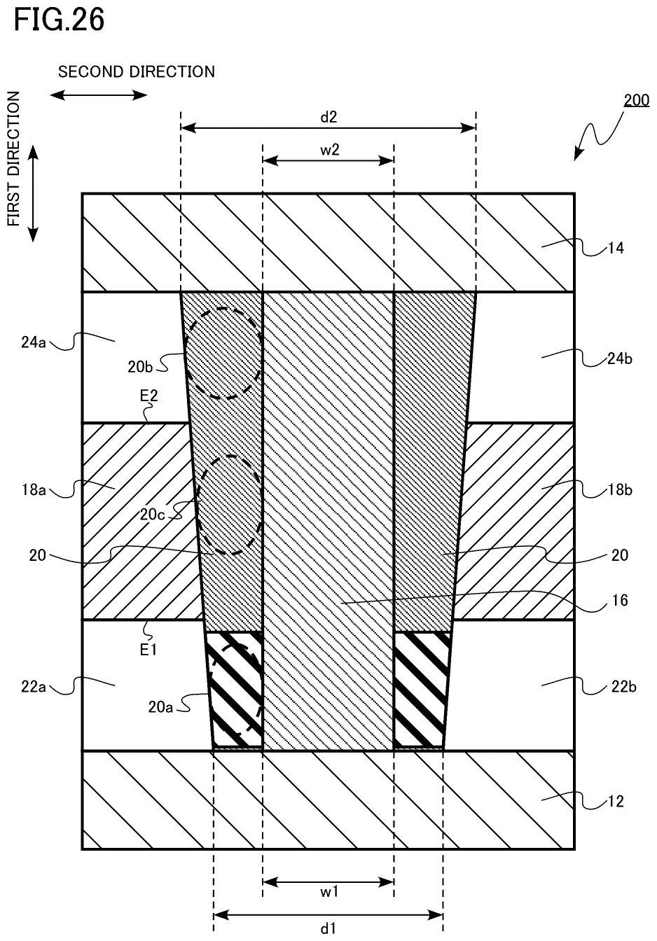

FIG. 26 is a schematic cross-sectional view of the semiconductor device according to the second embodiment. FIG. 26 is a diagram corresponding to FIG. 1 of the first embodiment.

The semiconductor device according to the second embodiment is a transistor 200. In the transistor 200, a gate insulating layer 20 provided between a second interlayer insulating layer 24 and an oxide semiconductor layer 16 and a gate insulating layer 20 provided between a gate electrode 18 and the oxide semiconductor layer 16 contain a material different from that of a gate insulating layer 20 provided between a first interlayer insulating layer 22 and the oxide semiconductor layer 16.

A first region 20a shown in FIG. 26 is a part of the gate insulating layer 20 provided between the first interlayer insulating layer 22 and the oxide semiconductor layer 16. In addition, a second region 20b is a part of the gate insulating layer 20 provided between the second interlayer insulating layer 24 and the oxide semiconductor layer 16. In addition, a third region 20c is a part of the gate insulating layer 20 provided between the gate electrode 18 and the oxide semiconductor layer 16. The second region 20b and the third region 20c contain a material different from that of the first region 20a.

The first region 20a contains, for example, silicon nitride. The first region 20a is formed of, for example, silicon nitride. In addition, the second region 20b contains, for example, silicon oxide. The second region 20b is formed of, for example, silicon oxide. The third region 20c contains, for example, silicon oxide. The third region 20c is formed of, for example, silicon oxide.

The transistor 200 according to the second embodiment can be formed, for example, by leaving a part of the first silicon nitride film 35 in the opening 34 when removing the first silicon nitride film 35 and the second silicon nitride film 36 by etching in the method for manufacturing the semiconductor device according to the first embodiment (FIG. 12).

For example, since the second region 20b contains a material having a dielectric constant different from that of the first region 20a, the strength of the fringe electric field between the gate electrode 18 and the oxide semiconductor layer 16 can be adjusted. Therefore, for example, by adjusting the difference between the parasitic resistance of the oxide semiconductor layer 16 between the gate electrode 18 and the upper electrode 14 and the parasitic resistance of the oxide semiconductor layer 16 between the gate electrode 18 and the lower electrode 12, it is possible to realize the optimal transistor characteristics.

As described above, according to the second embodiment, the reliability of the gate insulating layer 20 is improved to realize a semiconductor device with excellent transistor characteristics.

### Third Embodiment

A semiconductor device according to a third embodiment is different from the semiconductor device according to the first embodiment in that a gate insulating layer includes a first film provided between a gate electrode and an oxide semiconductor layer and containing a first material and a second film provided between the first film and the oxide semiconductor layer and containing a second material different from the first material and that the gate insulating layer further includes a third film provided between the second film and the oxide semiconductor layer and containing the first material. Hereinafter, the description of a part of the content overlapping the first embodiment may be omitted.

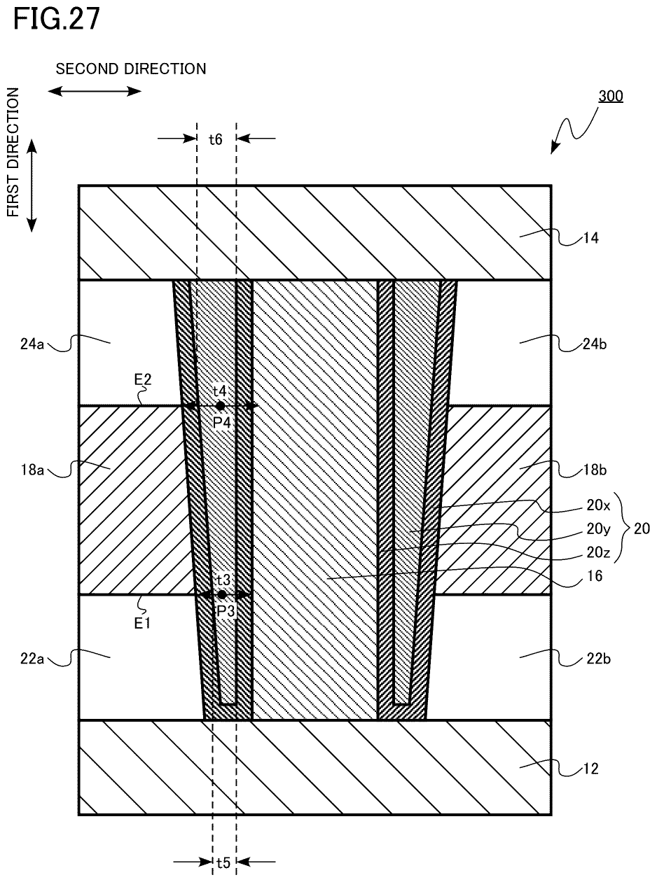

FIG. 27 is a schematic cross-sectional view of the semiconductor device according to the third embodiment. FIG. 27 is a diagram corresponding to FIG. 1 of the first embodiment.

The semiconductor device according to the third embodiment is a transistor 300. A gate insulating layer 20 of the transistor 300 includes a first film 20x, a second film 20y, and a third film 20z. The gate insulating layer 20 of the transistor 300 includes a stacked film of the first film 20x, the second film 20y, and the third film 20z.

The first film 20x and the second film 20y are in contact with each other and the second film 20y and the third film 20z are in contact with each other, for example. The first film 20x and the third film 20z are physically continuous with each other, for example, on the side of the gate insulating layer 20 facing the lower electrode 12.

The first film 20x contains the first material. The second film 20y contains the second material. The third film 20z contains the first material. The first film 20x and the third film 20z contain the same material.

The first film 20x is formed of, for example, a first material. The second film 20y is formed of, for example, a second material. The third film 20z is formed of, for example, a first material. The first film 20x and the third film 20z are formed of, for example, the same material.

The first material is, for example, an oxide, a nitride, or an oxynitride. The first material is, for example, a silicon oxide, an aluminum oxide, a titanium oxide, a tantalum oxide, a hafnium oxide, a silicon nitride, an aluminum nitride, or a silicon oxynitride.

The second material is a material different from the first material. The third material is, for example, an oxide, a nitride, or an oxynitride. The first material is, for example, a silicon oxide, an aluminum oxide, a titanium oxide, a tantalum oxide, a hafnium oxide, a silicon nitride, an aluminum nitride, or a silicon oxynitride.

For example, the first material is a nitride, and the second material is an oxide. For example, the first material is a silicon nitride, and the second material is a silicon oxide.

The second material is, for example, a material having a higher dielectric constant than the first material. The second material is, for example, a material having a higher dielectric constant than silicon oxide. For example, the first material is a silicon oxide, and the second material is a titanium oxide. For example, the first material is a silicon nitride, and the second material is a titanium oxide.

When the second material is a material having a higher dielectric constant than the first material, for example, in the first cross section, a fifth thickness (t5 in FIG. 27) of the second film 20y between the first end E1 of the gate electrode 18 and the oxide semiconductor layer 16 is smaller than a sixth thickness (t6 in FIG. 27) of the second film 20y between the second end E2 of the gate electrode 18 and the oxide semiconductor layer 16.

In the transistor 300, a fourth thickness t4 of the gate insulating layer 20 between the second end E2 of the gate electrode 18 and the oxide semiconductor layer 16 is larger than a third thickness t3 of the gate insulating layer 20 between the first end E1 of the gate electrode 18 and the oxide semiconductor layer 16. For this reason, for example, the channel resistance immediately below the second end E2 of the gate electrode 18 is higher than the channel resistance immediately below the first end E1 of the gate electrode 18.

However, in the transistor 300, the difference between the equivalent oxide thickness (EOT) of the gate insulating layer 20 at a fourth position P4 and the equivalent oxide thickness of the gate insulating layer 20 at a third position P3 can be reduced by setting the second material to a material having a higher dielectric constant than the first material and making the fifth thickness t5 of the second film 20y smaller than the sixth thickness t6 of the second film 20y. Therefore, it is possible to reduce the difference between the channel resistance immediately below the second end E2 of the gate electrode 18 and the channel resistance immediately below the first end E1 of the gate electrode 18.

The transistor 300 according to the third embodiment can be manufactured, for example, by using a stacked film instead of the third silicon oxide film 38 when filling the opening 34 with the third silicon oxide film 38 that finally becomes the gate insulating layer 20 in the method for manufacturing the semiconductor device according to the first embodiment.

In the transistor 300 according to the third embodiment, as in the first embodiment, the reliability of the gate insulating layer 20 is improved. In addition, in the transistor 300, since a stacked film is used for the gate insulating layer 20, the transistor characteristics are further improved.

### First Modification Example

A semiconductor device according to a first modification example of the third embodiment is different from the semiconductor device according to the third embodiment in that the first film is spaced from the first electrode.

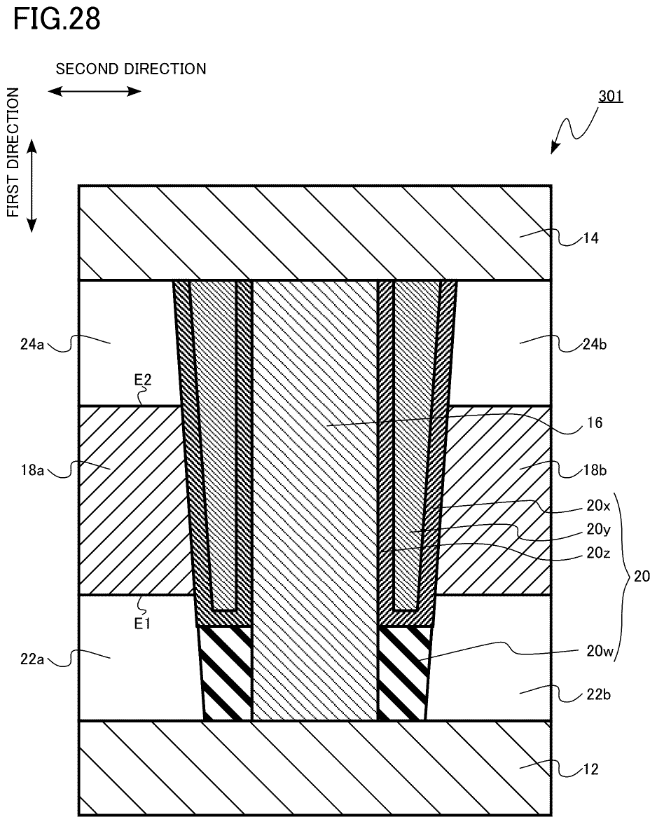

FIG. 28 is a schematic cross-sectional view of the semiconductor device according to the first modification example of the third embodiment. FIG. 28 is a diagram corresponding to FIG. 27 of the third embodiment.

The semiconductor device according to the first modification example of the third embodiment is a transistor 301. A gate insulating layer 20 of the transistor 301 includes a first film 20x, a second film 20y, a third film 20z, and a fourth film 20w.

The first film 20x is spaced from the lower electrode 12 in the first direction. The second film 20y is spaced from the lower electrode 12 in the first direction. The third film 20z is spaced from the lower electrode 12 in the first direction.

Between the first film 20x and the lower electrode 12, the fourth film 20w is provided. Between the second film 20y and the lower electrode 12, the fourth film 20w is provided. Between the third film 20z and the lower electrode 12, the fourth film 20w is provided.

The fourth film 20w contains a third material. The third material is, for example, a material different from the second material. The third material is, for example, an oxide, a nitride, or an oxynitride. The third material is, for example, a silicon oxide, an aluminum oxide, a titanium oxide, a tantalum oxide, a hafnium oxide, a silicon nitride, an aluminum nitride, or a silicon oxynitride.

In the transistor 301 according to the first modification example of the third embodiment, as in the first embodiment, the reliability of the gate insulating layer 20 is improved. In addition, in the transistor 301, since a stacked film is used for the gate insulating layer 20, the transistor characteristics are further improved.

### Second Modification Example

A semiconductor device according to a second modification example of the third embodiment is different from the semiconductor device according to the third embodiment in that the gate insulating layer does not include the third film.

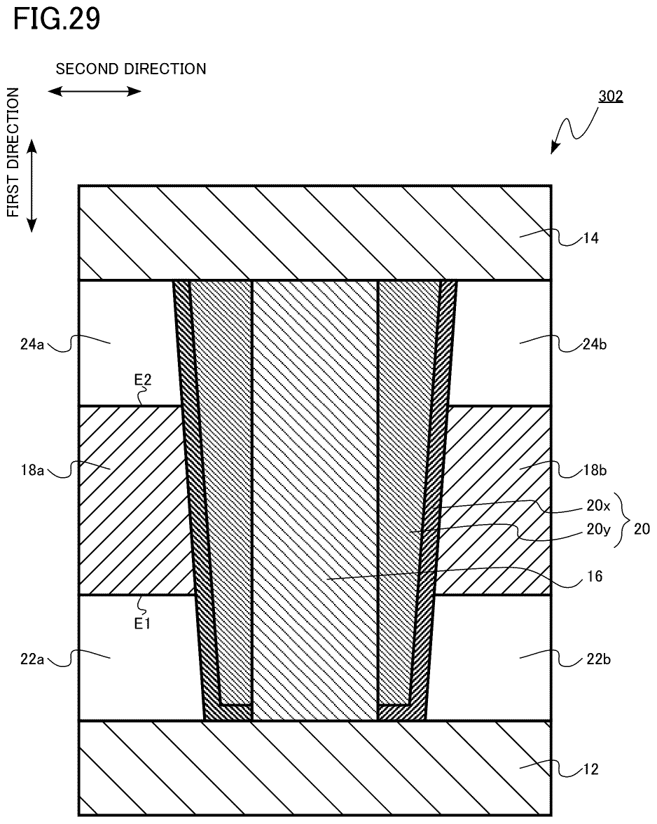

FIG. 29 is a schematic cross-sectional view of the semiconductor device according to the second modification example of the third embodiment. FIG. 29 is a diagram corresponding to FIG. 27 of the third embodiment.

The semiconductor device according to the second modification example of the third embodiment is a transistor 302. A gate insulating layer 20 of the transistor 302 includes a first film 20x and a second film 20y. The gate insulating layer 20 of the transistor 302 is different from the gate insulating layer 20 in the third embodiment in that the gate insulating layer 20 of the transistor 302 does not include the third film 20z.

In the transistor 302 according to the second modification example of the third embodiment, as in the first embodiment, the reliability of the gate insulating layer 20 is improved. In addition, in the transistor 302, since a stacked film is used for the gate insulating layer 20, the transistor characteristics are further improved.

As described above, according to the third embodiment and its modification examples, the reliability of the gate insulating layer 20 is improved to realize a semiconductor device with excellent transistor characteristics.

### Fourth Embodiment

A semiconductor memory device according to a fourth embodiment includes the semiconductor device according to the first embodiment and a capacitor electrically connected to either the first electrode or the second electrode.

The semiconductor memory device according to the fourth embodiment is a semiconductor memory 400. The semiconductor memory device according to the fourth embodiment is a DRAM. In the semiconductor memory 400, the transistor 100 according to the first embodiment is used as a switching transistor of a memory cell in a DRAM.

Hereinafter, the description of a part of the content overlapping the first embodiment will be omitted.

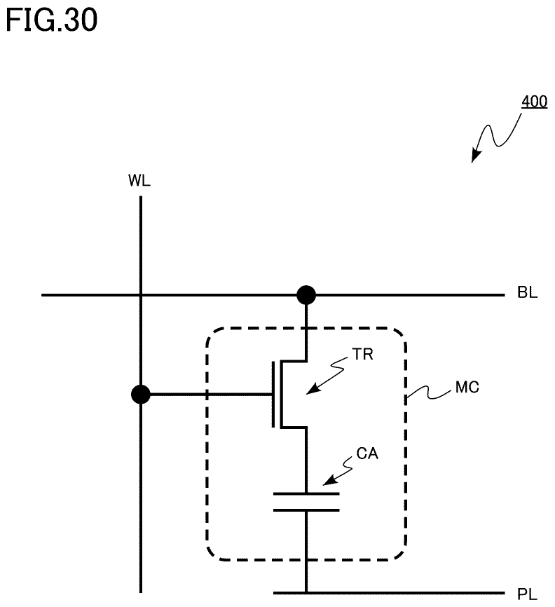

FIG. 30 is an equivalent circuit diagram of the semiconductor memory device according to the fourth embodiment. FIG. 30 illustrates a case where one memory cell MC is provided. However, for example, a plurality of memory cells MC may be provided in an array.

The semiconductor memory 400 includes the memory cell MC, a word line WL, a bit line BL, and a plate line PL. The memory cell MC includes a switching transistor TR and a capacitor CA. In FIG. 30, a region surrounded by the broken line is the memory cell MC.

The word line WL is electrically connected to the gate electrode of the switching transistor TR. The bit line BL is electrically connected to one of the source electrode and the drain electrode of the switching transistor TR. One electrode of the capacitor CA is electrically connected to the other one of the source electrode and the drain electrode of the switching transistor TR. The other electrode of the capacitor CA is connected to the plate line PL.

The memory cell MC stores data by storing charges in the capacitor CA. Data is written and read by turning on the switching transistor TR.

For example, data is written into the memory cell MC by turning on the switching transistor TR in a state in which a desired voltage is applied to the bit line BL.

In addition, for example, a voltage change in the bit line BL according to the amount of charge stored in the capacitor is detected by turning on the switching transistor TR, thereby reading the data of the memory cell MC.

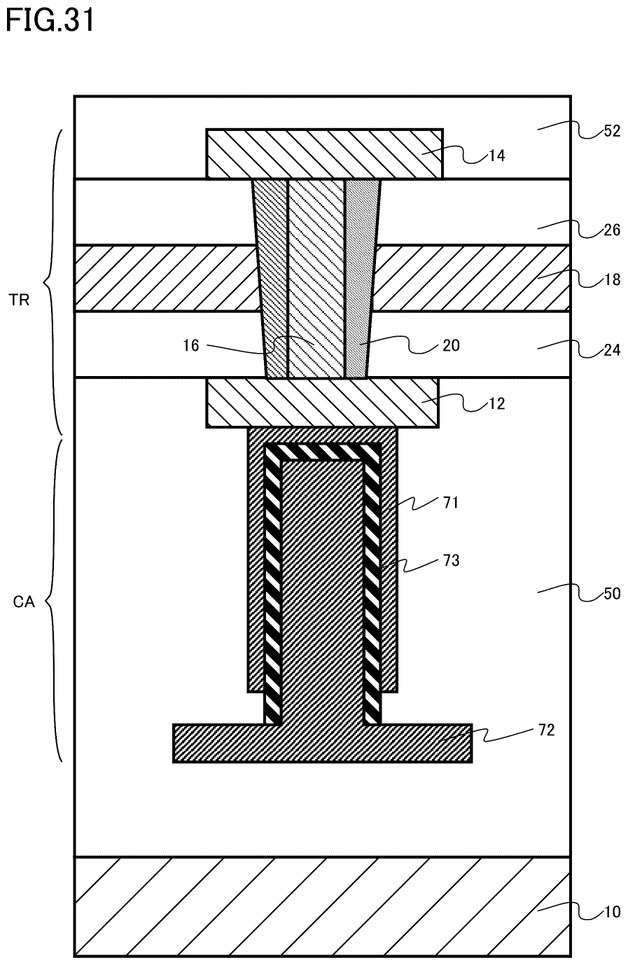

FIG. 31 is a schematic cross-sectional view of the semiconductor memory device according to the fourth embodiment. FIG. 31 shows a cross section of the memory cell MC of the semiconductor memory 400.

The semiconductor memory 400 includes a silicon substrate 10, the switching transistor TR, the capacitor CA, a lower insulating layer 50, and an upper insulating layer 52.

The switching transistor TR includes a lower electrode 12, an upper electrode 14, an oxide semiconductor layer 16, a gate electrode 18, a gate insulating layer 20, a first interlayer insulating layer 22, and a second interlayer insulating layer 24.

The switching transistor TR has a structure similar to that of the transistor 100 according to the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12. In addition, the capacitor CA can also be electrically connected to the upper electrode 14.

The capacitor CA includes a cell electrode 71, a plate electrode 72, and a capacitor insulating film 73. The cell electrode 71 is electrically connected to the lower electrode 12. The cell electrode 71 is in contact with, for example, the lower electrode 12.

Each of the cell electrode 71 and the plate electrode 72 is, for example, a titanium nitride. The capacitor insulating film 73 has, for example, a stacked structure of zirconium oxide, aluminum oxide, and zirconium oxide.

The gate electrode 18 is electrically connected to, for example, the word line WL (not shown). The upper electrode 14 is electrically connected to, for example, the bit line BL (not shown). The plate electrode 72 is connected to, for example, the plate line PL (not shown).

In the semiconductor memory 400, an oxide semiconductor transistor having a very small channel leakage current during off operation is applied as the switching transistor TR. Therefore, a DRAM having an excellent charge storage characteristic is realized.

In addition, the switching transistor TR of the semiconductor memory 400 has a highly reliable gate insulating layer 20. Therefore, the reliability of the semiconductor memory 400 is improved.

In the fourth embodiment, a semiconductor memory to which the transistor according to the first embodiment is applied has been described as an example. However, the semiconductor memory of embodiments may be a semiconductor memory to which the transistor according to the second embodiment or the third embodiment is applied.

According to the semiconductor memory device according to the fourth embodiment, it is possible to realize a semiconductor memory device with excellent transistor characteristics.

In the first to third embodiments, a GAA transistor in which a gate electrode is provided so as to surround an oxide semiconductor layer in which a channel is formed has been described as an example. However, the transistor of embodiments may be, for example, a double-gate transistor in which gate electrodes are provided so as to face each other on two sides of the oxide semiconductor layer in which a channel is formed, or may be a tri-gate transistor in which gate electrodes are provided so as to face each other on three sides of the oxide semiconductor layer in which a channel is formed.

While certain embodiments have been described, these embodiments have been presented by way of example only, and are not intended to limit the scope of the inventions. Indeed, the semiconductor device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
an oxide semiconductor layer provided between the first electrode and the second electrode;
a gate electrode facing the oxide semiconductor layer;
a first insulating layer provided between the first electrode and the gate electrode;
a second insulating layer provided between the gate electrode and the second electrode; and
a gate insulating layer provided between the gate electrode and the oxide semiconductor layer, between the first insulating layer and the oxide semiconductor layer, and between the second insulating layer and the oxide semiconductor layer,
wherein, in a first cross section parallel to a first direction connecting the first electrode and the second electrode, assuming that a thickness in a second direction perpendicular to the first direction of the gate insulating layer at a first position between the first insulating layer and the oxide semiconductor layer is a first thickness, a thickness in the second direction of the gate insulating layer at a second position between the second insulating layer and the oxide semiconductor layer is a second thickness, a thickness in the second direction of the gate insulating layer at a third position between a first end of the gate electrode on the first electrode side and the oxide semiconductor layer is a third thickness, and a thickness in the second direction of the gate insulating layer at a fourth position between a second end of the gate electrode on the second electrode side and the oxide semiconductor layer is a fourth thickness, the second thickness is larger than the first thickness or the fourth thickness is larger than the third thickness.

2. The semiconductor device according to claim 1,
wherein the second thickness is larger than the first thickness, and the fourth thickness is larger than the third thickness.

3. The semiconductor device according to claim 1,
wherein the second thickness is equal to or more than 1.1 times and equal to or less than 1.5 times the first thickness, or the fourth thickness is equal to or more than 1.1 times and equal to or less than 1.5 times the third thickness.

4. The semiconductor device according to claim 1,
wherein the gate electrode includes a first portion and a second portion in the first cross section, and
the oxide semiconductor layer is provided between the first portion and the second portion in the second direction.

5. The semiconductor device according to claim 1,
wherein the gate electrode surrounds the oxide semiconductor layer.

6. The semiconductor device according to claim 1,
wherein the first insulating layer includes a third portion and a fourth portion in the first cross section, and the oxide semiconductor layer is provided between the third portion and the fourth portion in the second direction, and
the second insulating layer includes a fifth portion and a sixth portion in the first cross section, and the oxide semiconductor layer is provided between the fifth portion and the sixth portion in the second direction.

7. The semiconductor device according to claim 6,
wherein a first distance in the second direction between a portion where the third portion is in contact with the first electrode and a portion where the fourth portion is in contact with the first electrode is smaller than a second distance in the second direction between a portion where the fifth portion is in contact with the second electrode and a portion where the sixth portion is in contact with the second electrode.

8. The semiconductor device according to claim 1,
wherein a first width in the second direction of a portion of the oxide semiconductor layer in contact with the first electrode in the first cross section is smaller than a second width in the second direction of a portion of the oxide semiconductor layer in contact with the second electrode in the first cross section.

9. The semiconductor device according to claim 7,
wherein a first width in the second direction of a portion of the oxide semiconductor layer in contact with the first electrode in the first cross section is smaller than a second width in the second direction of a portion of the oxide semiconductor layer in contact with the second electrode in the first cross section.

10. The semiconductor device according to claim 1,
wherein a first width in the second direction of a portion of the oxide semiconductor layer in contact with the first electrode in the first cross section is larger than a second width in the second direction of a portion of the oxide semiconductor layer in contact with the second electrode in the first cross section.

11. The semiconductor device according to claim 7,
wherein a first width in the second direction of a portion of the oxide semiconductor layer in contact with the first electrode in the first cross section is larger than a second width in the second direction of a portion of the oxide semiconductor layer in contact with the second electrode in the first cross section.

12. The semiconductor device according to claim 1,
wherein the gate insulating layer provided between the first insulating layer and the oxide semiconductor layer has a void.

13. The semiconductor device according to claim 1,
wherein the gate insulating layer provided between the second insulating layer and the oxide semiconductor layer and the gate insulating layer provided between the gate electrode and the oxide semiconductor layer contain a material different from a material of the gate insulating layer provided between the first insulating layer and the oxide semiconductor layer.

14. The semiconductor device according to claim 1,
wherein the gate insulating layer includes a first film provided between the gate electrode and the oxide semiconductor layer and containing a first material and a second film provided between the first film and the oxide semiconductor layer and containing a second material different from the first material.

15. The semiconductor device according to claim 14,
wherein the gate insulating layer further includes a third film provided between the second film and the oxide semiconductor layer and containing the first material.

16. The semiconductor device according to claim 14,
wherein a dielectric constant of the second material is higher than a dielectric constant of the first material.

17. The semiconductor device according to claim 15,
wherein a dielectric constant of the second material is higher than a dielectric constant of the first material.

18. The semiconductor device according to claim 17,
wherein, in the first cross section, a fifth thickness in the second direction of the second film between the first end and the oxide semiconductor layer is smaller than a sixth thickness in the second direction of the second film between the second end and the oxide semiconductor layer.

19. The semiconductor device according to claim 14,
wherein the first film is spaced from the first electrode.

20. A semiconductor memory device, comprising:
the semiconductor device according to claim 1; and
a capacitor electrically connected to either the first electrode or the second electrode.
